(19) United States
(12) Patent Application Publication
(10) Pub. No.: US 2026/0282592 A1
(43) Pub. Date: Sep. 17, 2026

(54) METHODS AND SYSTEMS FOR CONTINUOUS ROLL-TO-ROLL MANUFACTURING OF PHOTOVOLTAIC STRUCTURES

(71) Applicant: Energy Materials Corporation, Rochester, NY (US)

(72) Inventors: Stephan J. DeLuca, Meadville, PA (US); Thomas Nathaniel Tombs, Rochester, NY (US)

(21) Appl. No.: 19/470,983

(22) PCT Filed: Apr. 5, 2024
(86) PCT No.: PCT/US2024/023307

§ 371 Date: Sep. 30, 2025

Related U.S. Application Data
(60) Provisional application No. 63/457,545, filed on Apr. 6, 2023.

(51) Int. Cl. H10F 71/10; C23C 14/56; C23C 16/54; H10F 71/00

(52) U.S. Cl. CPC H10F 71/107; C23C 14/562; C23C 16/545; H10F 71/138

(57) ABSTRACT

A method of making a photovoltaic structure by roll-to-roll manufacturing includes conveying a continuous substrate from a dispensing roll at ambient pressure to a reduced pressure metal oxide deposition station, depositing a metal oxide layer over the continuous substrate under reduced pressure, and transporting the continuous substrate having the metal oxide layer to a take up roll at ambient pressure, wherein the continuous substrate extends continuously from the dispensing roll to the take up roll.

### TECHNICAL FIELD

The present disclosure relates to methods and systems for making photovoltaic structures by roll-to-roll manufacturing processes, in particular for making perovskite photovoltaic structures.

### BACKGROUND

Since their first report in 2009, rapid improvements have enabled perovskite solar cells (PSCs) to become a promising technology for converting light to electricity as part of optoelectronic devices. To date, the power conversion efficiencies (PCEs) of solution-processed PSCs have been certified above 25 percent, which is higher than the current dominant photovoltaic technology based on multi-crystalline silicon. Whereas crystalline silicon is rigid, brittle, and requires costly, energy-intensive fabrication procedures, perovskites are flexible, easily processed at low temperatures, and up to a thousand times thinner. Furthermore, perovskites are solution-processable, which enables their manufacture with scalable, low-cost methods. These attributes open new opportunities to integrate solar power creatively and inexpensively into previously inaccessible markets, such as electric vehicles and buildings. PSCs also have the important advantage of maintaining acceptable PCE as the temperature increases, unlike silicon-based solar cells, which exhibit significant power loss in typical operating environments. The manufacturing and PCE advantages of PSCs have put them on the path to be the next generation technology for utility, commercial, and residential photovoltaic applications.

Most top performing PSCs reported in the literature have been fabricated by lab-scale, spin-coating methods, which are unsuitable for high throughput and scalable module production. Forming high-performing, uniform, and defect-free multilayer structures on flexible substrates to make PSCs in a cost-effective manner has remained an elusive goal. This is also the case for organic solar cells and numerous other multilayer energy conversion structures. Roll-to-roll manufacturing has significant potential to make PSCs cost advantaged compared to traditional silicon-based solar cells. However, roll-to-roll manufacturing has numerous challenges that need to be overcome.

Despite research into various approaches, photovoltaics (PVs) based primarily on perovskites have yet to make a large market impact due at least in part to some of the unresolved problems noted above.

### SUMMARY

There remains a desire for photovoltaic devices such as PSC devices that can be reliably manufactured at large scale, at high speeds, at low cost, having high PCEs, and suitable lifetime.

In accordance with an embodiment of this disclosure, a method of making a photovoltaic structure by continuous roll-to-roll manufacturing includes, at a splicing station at ambient pressure, splicing an end portion of a first PV substrate roll to a starting portion of a second PV substrate roll thereby forming a continuous substrate having a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness. The method includes transporting the continuous substrate to a reduced-pressure metal oxide deposition station and depositing a metal oxide layer over the continuous substrate. The reduced pressure metal oxide deposition station includes an entry slot and an exit slot through which the continuous substrate enters and exits the reduced pressure metal oxide deposition station. The entry and exit slots each have a slot height that is less than 3× the splice thickness.

In accordance with another embodiment of this disclosure, a method of making a photovoltaic structure by continuous roll-to-roll manufacturing includes, at a splicing station at ambient pressure, splicing an end portion of a first PV substrate roll to a starting portion of a second PV substrate roll thereby forming a continuous substrate including a splice, wherein the end portion is characterized by a first substrate thickness, the starting portion is characterized by a second substrate thickness, and the splice is characterized by a splice thickness that is equal to or less than 1.5× the sum of first substrate thickness and the second substrate thickness. The method includes transporting the continuous substrate to a spatial atomic layer deposition (SALD) station and depositing a metal compound layer over the continuous substrate.

In accordance with yet another embodiment, a method of making a photovoltaic structure by roll-to-roll manufacturing includes conveying a continuous substrate from a dispensing roll at ambient pressure to a reduced pressure metal oxide deposition station and depositing a metal oxide layer over the continuous substrate under reduced pressure. The continuous substrate having the metal oxide layer is transported to a take up roll at ambient pressure. The continuous substrate extends continuously from the dispensing roll to the take up roll.

In accordance with another embodiment, method of making a photovoltaic structure by roll-to-roll manufacturing includes conveying a continuous substrate from a dispensing roll through a series of processing stations to a take up roll. The continuous substrate extends continuously from the dispensing roll to the take up roll. The series of processing stations includes i) a spatial atomic layer deposition station, and ii) a photoactive layer deposition station that includes at least an active absorber material coating apparatus.

In accordance with another embodiment of this disclosure, a manufacturing system for making a photovoltaic structure is provided, which includes a splicing station at ambient pressure for splicing an end portion of a first PV substrate roll to a starting portion of a second PV substrate roll thereby forming a continuous substrate including a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness. The system may include an optional first patterned metal deposition station for printing a bottom set of metal lines over the continuous substrate. The system may include a bottom conducting layer deposition station for depositing a bottom conducting layer over and in contact with the bottom set of metal lines to form a bottom electrode. The system further includes a first carrier transport layer deposition station for depositing a first carrier transport layer over the bottom electrode, a photoactive layer deposition station comprising a solution coating apparatus for forming a photoactive absorber layer over the first carrier transport layer, a second carrier transport layer deposition station for depositing a second carrier transport layer over the photoactive absorber layer, a transparent top conducting layer deposition station for depositing a top conducting layer over the second carrier transport layer, and a second patterned metal deposition station for printing a top set of metal lines over and in contact with the top conducting layer to form a transparent top electrode.

The present disclosure provides for PV devices and methods of their manufacture that may have one or more of the following advantages relative to conventional PV technology: improved manufacturing scalability, shorter manufacturing takt times, reduced manufacturing costs, simplified manufacturing processes; reduced manufacturing defects; more reproducible manufacturing processes; reduced environmental impact; improved areal PCE; lower resistance electrodes; electrodes with higher optical transparency; increased physical durability or increased lifetime.

### BRIEF DESCRIPTION OF DRAWINGS

FIG. 1 is a cross-sectional view of a non-limiting example of a perovskite photovoltaic structure according to some embodiments.

FIG. 2 is a schematic view of a non-limiting example of a roll-to-roll PV structure manufacturing system according to some embodiments.

FIG. 3A is a schematic cross-sectional view of a splice station according to some embodiments.

FIGS. 3B and 3C are cross-sectional views of some non-limiting examples of splices according to some embodiments.

FIG. 4A is a schematic cross-sectional view of an RPMO deposition station according to some embodiments.

FIG. 4B is a cross-sectional schematic of a non-limiting example of a splice traversing a slot according to some embodiments.

FIG. 4C is a cross-sectional schematic of a non-limiting example of an adjustable slot according to some embodiments.

FIG. 4D is a cross-sectional schematic of a non-limiting example of an adjustable slot with rollers according to some embodiments.

FIG. 5A is a schematic cross-sectional view of an SALD station according to some embodiments.

FIG. 5B is a closeup cross-sectional view of the manifold illustrating an overlap splice about to traverse the area according to some embodiment.

FIG. 6 is a top view of a non-limiting example of a set of metal lines according to some embodiments.

It is to be understood that the drawings are for purposes of illustrating the concepts of the disclosure and may not be to scale. Terms like “overlaying”, “over” or the like include, but do not necessarily require, direct contact (unless such direct contact is noted or clearly required for functionality). Additional details of certain embodiments of the present application may be found in U.S. Pat. Nos. 11,108,007, 11,342,130, U.S. Application No. 2020/0377532, and U.S. Application Publication No. 2022/0238807, the entire contents of which are incorporated herein by reference for all uses.

A perovskite photovoltaic structure is intended to receive light (typically visible, IR, or UV light) and convert it into electricity. As such, various layers and features may need to be reasonably transparent to this light to ensure that an appropriate amount reaches the perovskite layer(s). Herein, unless otherwise noted, the terms “transparent”, “transparency”, “transmissivity” or the like, are generally relative to the target wavelength or wavelength range for conversion to electricity. This target wavelength or wavelength range may be different for different systems. In some embodiments, the target wavelength range may correspond to the solar radiation spectrum or a portion thereof. In some cases, the target wavelength range may correspond to the visible light spectrum or a portion thereof. In some cases, the target wavelength range may correspond to the infrared or UV spectrum, or a portion thereof. In some embodiments, the target wavelength range may be defined as a particular wavelength, e.g., as 550 nm, or any other wavelength of interest. In some cases, a target wavelength range may be defined as an explicit range, e.g., 525-575 nm, or any other wavelength range of interest. Something that is “transparent” generally transmits at least 50% of incident radiation within the target wavelength range. In many cases, the transmissivities of various features may be significantly higher than this.

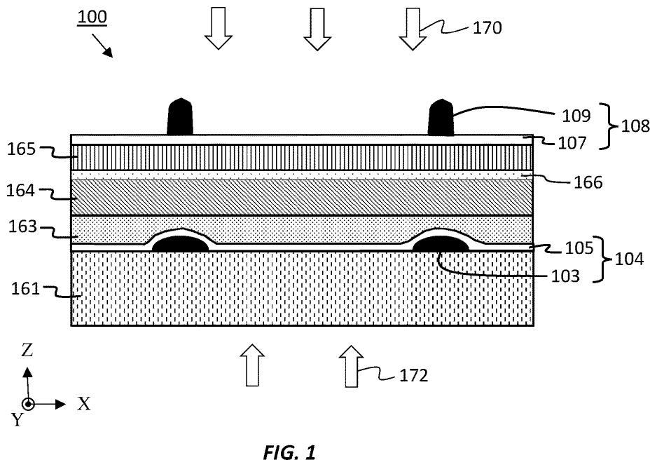

Perovskite PV structure Before discussing roll-to-roll manufacturing, it is useful to first consider some general photovoltaic structures that may be desired. FIG. 1 is a cross-sectional view of a non-limiting example of a perovskite photovoltaic structure according to some embodiments. For added perspective, XYZ coordinate axes are also shown. In some cases, photovoltaic structure 100 may include a flexible transparent substrate 161. A transparent bottom electrode 104 may be provided over the substrate. In some embodiments, as shown in FIG. 1, transparent bottom electrode 104 may be a transparent composite conductor including a bottom set of conductive metal lines 103 and a transparent bottom conducting layer 105 provided in contact with the bottom set of metal lines. In some preferred embodiments and as shown in FIG. 1, the bottom set of conductive metal lines 103 may be provided over the transparent substrate 161 and the bottom conducting layer 105 may be provided over the bottom set of metal lines and over the transparent substrate. Although illustrated as a conformal coating, the bottom conducting layer may in some cases act as a smoothing layer and may partially or fully planarize the structure. In some other embodiments, not shown, the bottom conducting layer may instead be provided over the transparent substrate and the bottom set of metal lines provided over the bottom conducting layer. In some embodiments, the bottom set of metal lines may be silver or copper. In some embodiments, the bottom set of metal lines may be printed, e.g., by flexography. In some embodiments the transparent bottom conducting layer may include a conductive metal oxide such as ITO, AZO, or the like. In some cases, the bottom conducting layer may be deposited by a reduced pressure metal oxide deposition station that is compatible with roll-to-roll manufacturing. In some cases, the bottom conducting layer may be deposited by an SALD process that is compatible with roll-to-roll manufacturing.

A first carrier transport layer 163 may be provided overlaying the bottom electrode 104. Although illustrated as planarizing, the first carrier transport layer may in some cases be a conformal coating or partially planarizing or even substantially planarizing. In some preferred embodiments, the first carrier transport layer 163 is generally not in direct contact with the bottom set of metal lines 103. A perovskite absorbing layer 164 (which may also be referred to simply as a perovskite layer) may be provided overlaying the first carrier transport layer. A second carrier transport layer 165 may be provided overlaying the perovskite absorbing layer. In some cases, at least the perovskite absorbing layer is provided by solution coating. In some cases, one or both of the first and second carrier transport layers are provided by solution coating. In some embodiments, a passivation layer 166 may optionally be provided between the perovskite absorbing layer 164 and the second carrier transport layer 165. In some cases a passivation layer may act as a barrier to diffusion of solvents, metal ions and/or halide ions. A passivation may in some embodiments include an electrically insulating metal oxide (e.g., aluminum oxide, titanium dioxide, or the like) that is sufficiently thin so as not to seriously impede the transport of charge between layers. In some embodiments, a passivation layer may be less than 6 nm, alternatively less than 2 nm. In some embodiments, a passivation may be applied by SALD.

A transparent top electrode 108 may be provided over the second carrier transport layer. The transparent top electrode may in some embodiments be a top composite conductor including a transparent top conducting layer 107 and a top set of conductive metal lines 109 provided in contact with the top conducting layer. In some preferred embodiments, the top set of metal lines are generally not in direct contact with the second carrier transport layer 165. That is, and as shown in FIG. 1, the top conducting layer may be provided over the second carrier transport layer and the top set of conductive metal lines may be provided over the top conducting layer. In some other embodiments, not shown, the top set of metal lines may be provided over the second carrier transport layer and the top conducting layer may be provided over the second set of metal lines and over the second carrier transport layer. In some embodiments (not shown), a passivation layer may optionally be applied between the second carrier transport layer 165 and the transparent top conducting layer 107.

In some embodiments, the top set of metal lines may be silver or copper. In some embodiments, the top set metal lines may be printed, e.g., by flexography. In some embodiments the transparent top conducting layer may include a conductive metal oxide such as ITO, AZO, or the like. In some cases, the top conducting layer may be deposited by a reduced pressure metal oxide deposition station that is compatible with roll-to-roll manufacturing. In some cases, the top conducting layer may be deposited by an SALD process that is compatible with roll-to-roll manufacturing.

As shown in FIG. 1, photovoltaic structure 100 may in some cases be a bifacial photovoltaic structure capable of receiving light 170 from its upper surface and light 172 from its lower surface. In some embodiments, light 170 may be more intense than light 172. For example, light 170 may include sunlight and light 172 may include reflected sunlight or other ambient light source.

In some embodiments, the first carrier transport layer may include a hole transporting material and the bottom electrode may act as an anode in the photovoltaic structure. In such embodiments, the second carrier transport layer may include an electron transporting material and the top electrode may act as a cathode in the photovoltaic structure. Such an arrangement of layers may for convenience be referred to as a PIN structure.

In some alternative embodiments, the first carrier transport layer may include an electron transporting material and the bottom electrode may act as cathode in the photovoltaic structure. In such embodiments, the second carrier transport layer may include a hole transporting material and the top electrode may act as an anode in the photovoltaic structure. Such an arrangement of layers may for convenience be referred to as a NIP structure.

In operation, positive and negative charges (holes and electrons) are produced in the perovskite absorbing layer 164 in response to absorption of appropriate radiation. The first and second carrier transport layers (163, 165) receive these separated charges and transfer them to the respective bottom and top electrodes (104, 108). The bottom and top electrodes may be in electrical contact with an electrical device (not shown in FIG. 1) where the collected charges serve to power the device, or alternatively charge it in the case where the electrical device is an energy storage battery of some sort.

Although FIG. 1 illustrates a bifacial PV structure, in some cases only one of the electrodes is transparent and the other may be opaque or have low transparency. In some preferred embodiments, at least the top electrode is transparent. Although more challenging to make in some ways, such a structure reduces the need for the substrate to be transparent or light stable, particularly to UV radiation. Many cost-effective substrate materials can yellow or become brittle with long term exposure to the sun, and a top transparent electrode system may reduce the burden on the substrate requirements.

In some embodiments, an opaque or low transmissivity electrode (e.g., the bottom electrode) may include a metal layer, or a metal/conductive metal oxide bilayer. The metal may be copper, aluminum, or some other metal with sufficient electrical conductivity. In some cases, the metal may be aluminum, e.g., aluminum coated PET substrate. In some embodiments using a composite conductor, rather than using a transparent conductive metal oxide as the conducting layer, less transparent carbon nanotubes, metal nanowires or the like may be used instead. In some cases, a passivation layer such as a metal oxide layer may be provided between the carbon nanotubes or metal nanowires and an adjacent carrier transport layer. In situations where the primary light source transmits light through the upper surface, this type of composite conductor may still allow useful light to be transmitted from the bottom. The transparency may be less than using a transparent metal oxide, but the impact on device performance in some cases may be low and the manufacturing or cost advantage may be high.

In some embodiments, a passivation layer such as a passivation metal oxide layer may be provided between any pair of adjacent layers. In some cases, a passivation layer may be deposited by SALD or a reduced pressure metal oxide deposition tool.

### Roll-to-Roll Manufacturing System

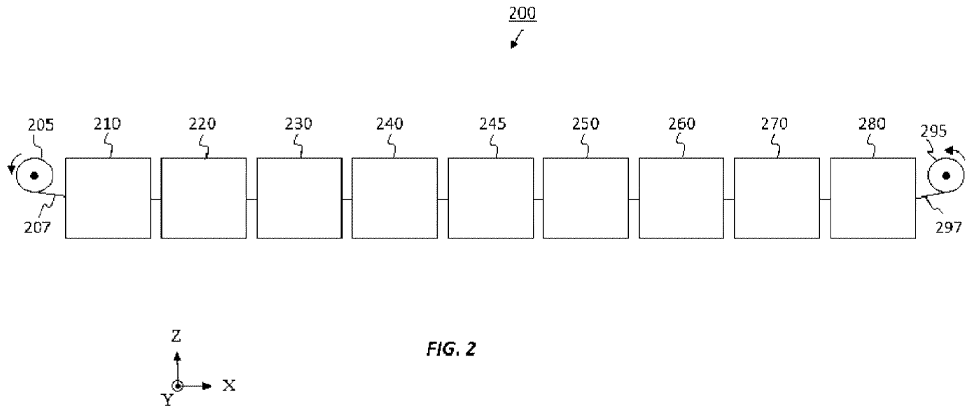

In some embodiments, the materials and methods used for forming one or more layers of the photovoltaic structure are compatible with roll-to-roll processing. FIG. 2 is a schematic view of a non-limiting example of a PV structure continuous roll-to-roll manufacturing system according to some embodiments. Continuous roll-to-roll manufacturing system 200 includes a first PV substrate roll 295 (which may also be referred to as a take up roll) which receives the PV structure that has been formed on the first substrate 297 as the substrate moved through the various manufacturing stations, 220, 230, 240, 245, 250, 260, 270, and 280. In this embodiment, the first substrate may extend back to splicing station 210 where it is spliced to a second substrate 207 provided on a second PV substrate roll 205 (which may also be referred to herein as a dispensing roll). Collectively, the spliced substrates 207 and 297 represent a continuous substrate. As opposed to processing one roll at a time, the ability to splice during manufacturing has the important advantage of allowing production to continue without stopping. Although not shown in FIG. 2, there may also be a roll cut station (after station 280) for starting new take-up rolls so that the rolled product can be moved on to next manufacturing steps.

Numerous configurations are possible for the present manufacturing system. In the configuration shown in FIG. 2, manufacturing station 220 may be a first patterned metal (“PM1”) deposition station, station 230 may be a first reduced pressure metal oxide (“RPMO1”) deposition station, station 240 may be a first carrier transport layer (“CTL1”) deposition station, station 245 may be a perovskite absorber layer (“PAL”) deposition station, station 250 may be a spatial ALD passivation layer (“SALD-PL”) deposition station, station 260 may be a second carrier transport layer (“CTL2”) deposition station, station 270 may be a second reduced pressure metal oxide (“RPMO2”) deposition station, and station 280 may be a second patterned metal (PM2) deposition station. In some embodiments (not shown), a final passivation layer station may be included after station 280 for stabilizing the product when wound onto PV roll 295. In some cases (not shown), a low adhesion separator film may be interleaved as part of the winding process of PV roll 295 so that the top of the PV structure does not directly touch the bottom of the substrate. Unless otherwise noted or clear from the context, the substrate (or web) shown in the figures are moving from left to right.

In some embodiments, the roll-to-roll manufacturing system may operate in continuous operation for long periods without the need to stop production to transfer rolls to some other station midway through PV structure build. In some embodiments, a continuous manufacturing operation includes at least one splicing event, but may include two or more. In some embodiments, a continuous manufacturing operation may extend at least 4 hours, alternatively at least 8 hours, 16 hours, 24 hours, 5 days, or even longer. At some point, various stations will eventually need maintenance. In some embodiments, maintenance could be automatic, for example a new doctor blade could be rapidly changed without stopping the substrate. This may cause a portion of the substrate to be not suitable for making product and the system will mark the portions of the substrate that are affected by the automatic maintenance. This marking system can also be used to identify the splice location. The methods and materials described herein can in some cases permit transport speeds of 5 m/min or greater, alternatively 30 m/min or greater, or even 100 m/min or greater. In some embodiments, the methods and materials described herein can allow production of 5 m²/min or even more of PV structure product, alternatively 50 m²/min or even more, or even 200 m²/min or even more.

### Splice Station

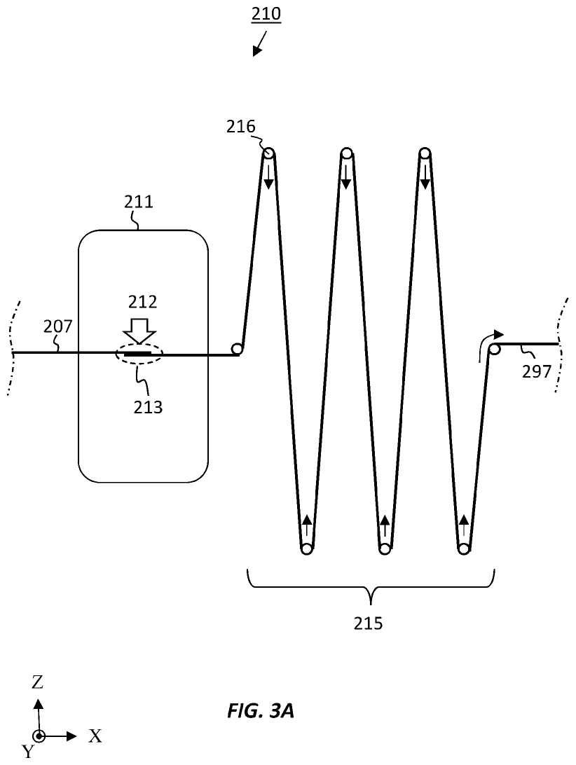

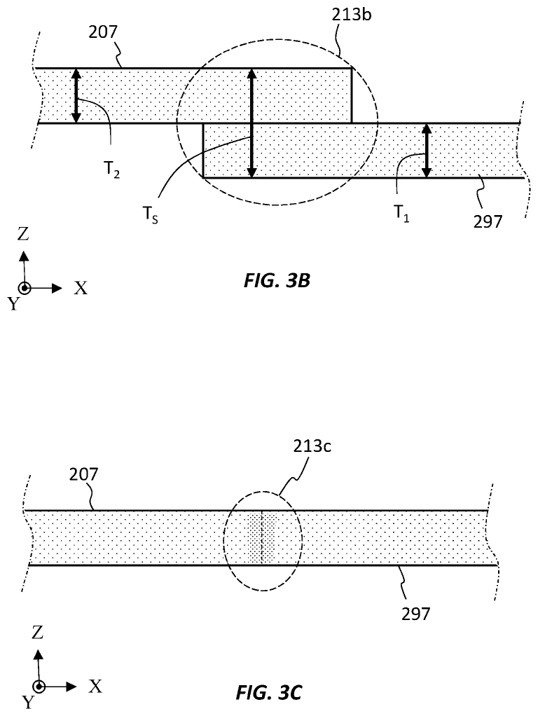

FIG. 3A is a schematic cross-sectional view of a splice station according to some embodiments. Splice station 210 may include a splicing device 211 for forming a splice 213 between first and second substrates, 297 and 207, respectively. In some embodiments, forming splice 213 may involve application of energy 212. Forming a splice may include application of laser energy (laser splice), ultrasonic energy (ultrasonic splice), temperature, pressure, an adhesive, or a solvent. In some preferred applications, the splice may be a laser splice or ultrasonic splice. When forming a splice, the two substrates may need to be held in place for a period of time. This can potentially disrupt the flow of roll-to-roll manufacturing system, so the splicing station may in some cases include an accumulator 215 where the substrate can be distributed between a series of movable rollers 216. This builds in some slack when needed. For example, during the time for making splice 213, the upper rollers may move down and/or the lower rollers may move up so that transport of substrate to the next station is maintained.

As discussed later, certain reduced pressure material deposition technologies, and in particular RPMO deposition technologies, have been found to be particularly useful in forming certain layers of a PV structure, e.g., a conductive layer of a composite electrode. However, it has also been found that the nature of the splice can have a significant impact on the performance of the RPMO deposition. In particular, some conventional splicing technologies employ two-sided splice tape between overlapping ends of the substrates being joined in an overlap splice, as well as (or alternatively) splice tape on either or both sides of both the top and bottom sides of an overlap splice or of a butt splice (where the two ends of the substrates being joined abut each other). Due to the thickness of splice tape (and in particular, the potential use of multiple pieces of splice tape above, between, and below the ends of the joined substrates), it has been found that such conventional tape splices can create a splice having a thickness at least several times the thickness of the substrate itself, which may be poorly compatible with the use of reduced pressure material deposition tools due to the relatively narrow gaps the substrate needs to be conveyed through to enter and leave such reduced pressure material deposition tools. Similarly, a relatively thick tape splice can be problematic in a SALD tool due to necessary tight tolerances for deposition distances when using such tools.

Although a tape splice may be used in some cases, in some embodiments, a tape splice is not used in order to reduce splice thicknesses. FIGS. 3B and 3C are cross-sectional views of some non-limiting examples of splices according to some embodiments. In FIG. 3B, the first and second substrates, 297 and 207, respectively, overlap (an overlap splice). The first substrate 297 may be characterized by a first substrate thickness T₁ and second substrate 207 may be characterized by a second substrate thickness T₂. While in most instances the first and second substrate thicknesses will be equal (e.g., for continuous production of an equivalent structure), they may be different when it is desired to change the substrate while maintaining a continuous process. In the overlapped region of splice 213b, the splice may be characterized by splice thickness T_{S}. In FIG. 3B, without the use of any splice tape, T_{S} may be approximately equal to the sum of T₁ and T₂. Although substrate 207 is shown in the overlap splice as being over substrate 297, the opposite configuration may be used where substrate 297 is provided over substrate 207 in an overlap splice. In some cases, a splice such as shown in FIG. 3B may be made from an ultrasonic weld (an ultrasonic splice), a laser weld (a laser splice), a hot air weld (a hot air splice), radiant weld using IR or UV radiation (radiant weld), or a solvent weld (solvent splice). In some cases, such splices do not substantially add thickness to the splice structure beyond the sum of the substrate thicknesses. In some cases, there may be a relatively small expansion. In some cases, a splice may include a thin adhesive layer or some other feature that may add some minor thickness to the splice.

In some embodiments, as shown in FIG. 3C, the first and second substrates 297 and 207, respectively, may abut each other and a splice 213c is formed at this interface (a butt splice). Such a splice may in some cases have a thickness that is even less than that of an overlap splice (e.g., FIG. 3B). A butt splice may be made using any of the previously mentioned splice technologies, but in some preferred embodiments, a butt splice may be made by a laser weld.

If necessary for sufficient splice strength, splice tape may be used in combination with any of the above mentioned ultrasonic, laser weld, hot air weld, radiant weld, or a solvent weld technologies, for either of an overlap splice or a butt splice. In such cases, fewer pieces of splice tape may need to be employed (e.g., a single piece of splice tape) to provide sufficient splice strength than in the absence of use of such additional splice technologies, resulting in a thinner splice thickness than in splices where multiple pieces of splice tape are used to provide sufficient splice strength.

In some preferred embodiments, splice thickness T_{S}≤3×(T₁+T₂), i.e., T_{S} is less than or equal to 3 times the sum of T₁ and T₂, alternatively less than or equal to 2 times the sum of T₁ and T₂, alternatively less than or equal to 1.5 times the sum of T₁ and T₂, alternatively less than or equal to 1.25 times the sum of T₁ and T₂, alternatively less than or equal to 1.1 times the sum of T₁ and T₂, alternatively within 10% of the sum of T₁ and T₂, alternatively less than or equal the sum of T₁ and T₂. For non-overlapping splices (e.g., butt splices), the splice thickness may alternatively be less than or equal to 2 times either of T₁ and T₂, alternatively less than or equal to 1.5 times either of T₁ and T₂, alternatively within 10% of either of T₁ or T₂. The splice thickness in general is preferably less than or equal to 3 times either of T₁ and T₂, more preferably less than or equal to 2 times either of T₁ and T₂, while for overlapping splices the splice thickness T_{S} is preferably less than or equal to 1.5 times the sum of T₁ and T₂, and for butt splices the splice thickness is preferably less than or equal to 1.5 times either of T₁ and T₂, more preferably less than 1 times either of T₁ and T₂. Note that if a tape splice is used, the thickness of the tape is also added when determining splice thickness.

In some embodiments, ultrasonic welding may use ultrasonic energy at high frequencies (e.g., 20-40 kHz) to produce low amplitude mechanical vibrations at an interface. The vibrations generate heat at the joint interface of the parts being welded, resulting in melting of the substrate materials and splice formation after cooling. An ultrasonic splice may in some cases be formed in less than 5 seconds, alternatively in less than 2 seconds, e.g., in a range of 0.1 and 1.0 seconds.

In some embodiments, laser welding may use a high energy laser beam to melt the substrate, e.g., at the interface. In some cases, the substrate or substrate surface may include a material that absorbs the laser radiation to promote heating and melting with formation of the laser splice upon cooling. In some cases, the laser may produce IR radiation or alternatively visible radiation. The laser may in some cases be focused at the substrate interface. The laser may in some cases be a CO₂ laser. The laser beam may be continuous, pulsed, or some combination.

In some cases, a solvent weld involves application of a liquid or gel that can dissolve or interact with the substrate surfaces to cause the substrate polymer material to mix at the interface. Upon dissipation of the solvent (e.g., by evaporation or diffusion), the interface sets to form a solvent splice.

A hot air weld may operate in a manner similar to an ultrasonic or laser weld where substrate material is caused to melt at the interface and the hot air splice is formed upon cooling.

A radiant weld may operate in a manner similar to an ultrasonic or laser weld where substrate material is caused to melt at the interface and the radiant splice is formed upon cooling. Absorption of the radiant light may be enhanced by the use of a coating that efficiently absorbs the wavelength of incident light.

An adhesive splice may include a thin layer of an adhesive applied between the substrates, e.g., an acrylate, an epoxy, or any adhesive capable of bonding to the substrates. Upon curing or setting, an adhesive splice may be formed. UV radiation may be used to cure the adhesive. In some cases, the adhesive layer does not require setting or curing. In preferable embodiments, the thickness of the adhesive layer used in an adhesive splice may be less than either substrate thickness, alternatively less than 80% of either substrate thickness, alternatively less than 50%, 40%, 30%, 20%, or 10%.

In some embodiments, conventional tape splices which provide tape material over, between, and/or under the substrates at their interface are not used unless the total splice thickness T_{S} can be made less than or equal to 1.5 times the sum of T₁ and T₂. It can be difficult to find an effective tape that can meet the desired thickness. Tape splices can be slow to make and the tape itself needs to be compatible with all of the other processing steps, which creates even further limitations on the choice of tape.

### RPMO Deposition Station(s)

Although FIG. 2, shows station 220 (which may be a patterned metal deposition station) as immediately following splice station 210, it is useful to first discuss the RPMO deposition station, e.g., RPMO1 or RPMO2. Whether it directly follows the splice station or is downstream, it still must be compatible with the splice.

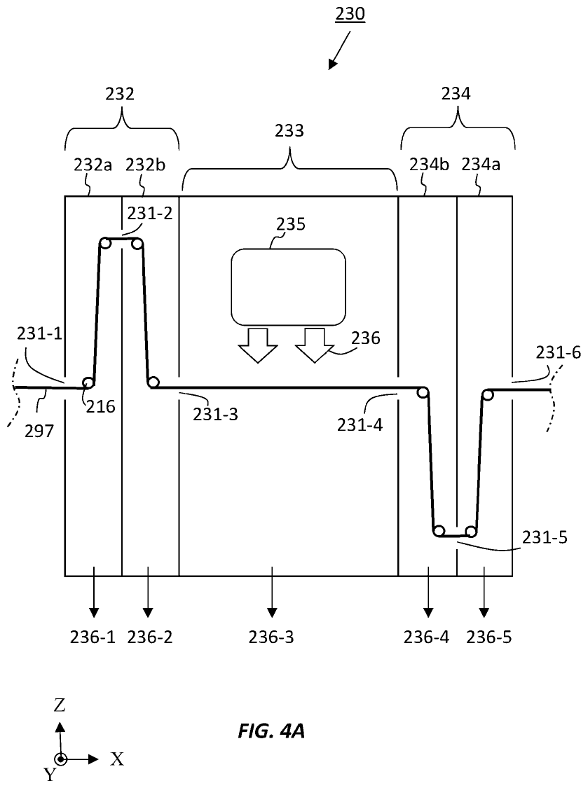

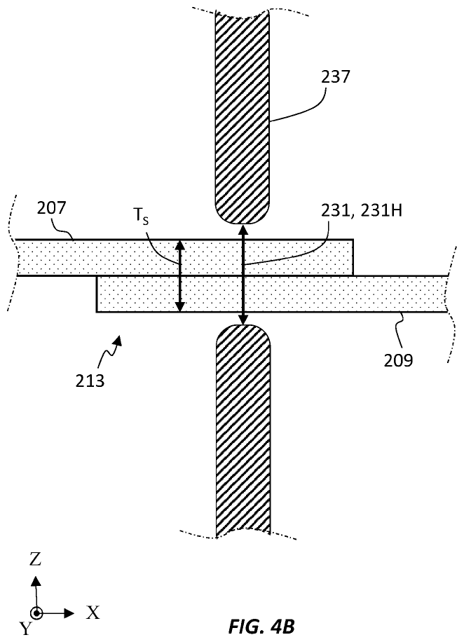

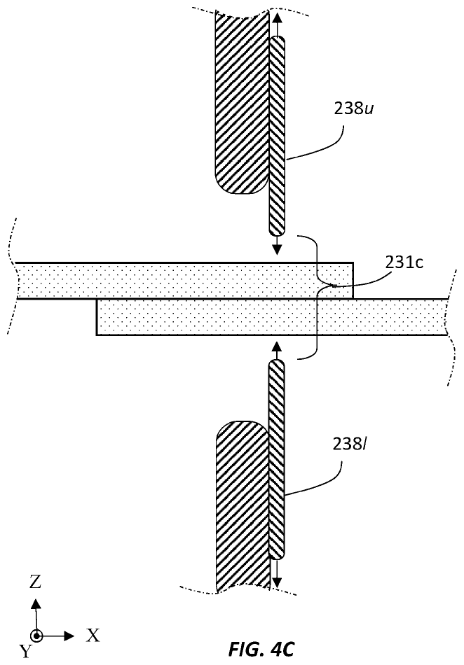

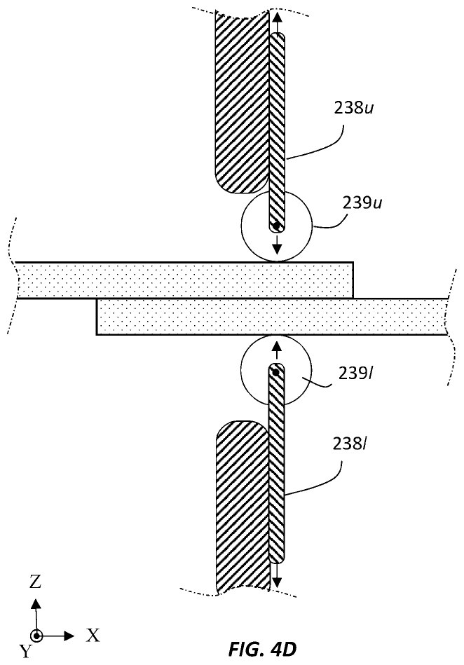

FIG. 4A is a schematic cross-sectional view of an RPMO deposition station according to some embodiments. RPMO deposition station 230 includes an entry chamber 232 that includes an entry slot 231-1 in an outer wall for receiving the substrate 297. Note that substrate 297 may have one or more additional layers provided thereon by the time the substrate reaches the RPMO deposition station. For convenience it is referred to herein simply as substrate 297, but it may instead be called a substrate structure. Entry chamber 232 may optionally include two or more sub chambers 232a and 232b and a slot 231-2 through which the substrate may traverse from sub chamber 232a to 232b. Entry chamber 232 is at a reduced pressure relative to outside of the RPMO deposition station. In some cases, sub chamber 232a may be at a reduced pressure relative to outside the RPMO tool (outside the tool may be ambient pressure), and sub chamber 232b may be at a pressure that is reduced relative to sub chamber 232b. That is, the sub chambers may step down the pressure as the substrate traverses through along rollers 216. Each sub chamber may have its own vacuum pump, e.g., vacuum pump 236-1 for sub chamber 232a and vacuum pump 236-2 for sub chamber 232b. For convenience, only a single roller is generally shown at the turns in substrate direction, but any of the rollers may be part of a multi-roller set, e.g., nip rollers. The rollers may extend across the entire substrate in the Y direction, or alternatively may be present just near the edges of the substrate. In some cases, rollers 216, particularly those that may contact layers coated onto the substrate, may be made from a relatively hard material such as metal, ceramic, or hard plastic, rather than a compressible material (e.g., rubber, foamed plastic, or the like). Hard surface rollers may in some cases be less prone to cause sheer forces that may damage coatings on the substrate. Hard rollers may optionally include a surface coating to reduce sticking or the like. Roller systems may in some cases include a self-cleaning mechanism (e.g., a wiper blade) to remove dirt/debris from the roller surface either continuously or periodically. Some rollers may be passive, i.e., freely rotate about an axle, or they may be active and turned by a drive system. Although not shown, the substrate and rollers may use sprocket-in-hole type technology.

Next, the substrate may move from entry chamber 232 to metal oxide deposition chamber 233 via slot 231-3. In some cases, metal oxide deposition chamber 233 may be at a pressure that is even lower than the pressure of sub chamber 232b using vacuum pump 236-3. The metal oxide deposition chamber may include deposition tool 235 for depositing the intended metal oxide coating material 236. Not shown, the RPMO deposition station may further include gas or other material supply that can be fed into the deposition tool 235, e.g., by tubing. In some cases, coating material 236 may include a metal oxide material or a precursor that forms the metal oxide layer over the substrate structure. Although the present discussion is directed mainly to metal oxides, it should be noted that other materials may be deposited in the reduced pressure material coating station. It is referred to herein as a reduced pressure metal oxide deposition station, but this is simply for convenience. Such a reduced pressure material coating tool may instead or additionally coat metal compounds other than oxides (nitrides, carbides, sulfides, organic complexes), or metals in their metallic state, or even non-metal compounds, such as silicon, silicates, carbon, organics, or the like. Anywhere the term “reduced pressure metal oxide deposition” or “RPMO deposition” is used herein, unless actually specifically directed towards metal oxide coatings embodiments, it may be replaced by “reduced pressure material deposition” and refer to material layers other than those including metal oxide. In some cases, a reduced pressure material deposition tool may be used to deposit a conductive layer, a passivation layer material or even a carrier transport layer material.

In some embodiments, deposition tool 235 may be use conventional sputtering, physical vapor deposition, chemical vapor deposition, atomic layer deposition, e-beam deposition, or other reduced pressure deposition technology. However, it can be difficult in some cases to achieve the low pressures needed for some of these methods. In some preferred cases, a metal oxide (or other material) may be deposited by so-called high-pressure sputtering that may operate above 0.01 mBar. In some preferred embodiments, a metal oxide (or other material) may be deposited from an aerosol of nanoparticles. Some non-limiting examples of aerosol-based deposition are described in U.S. Pat. No. 10,092,926, which is incorporated by reference herein in its entirety for all purposes. In some cases, aerosol deposition has been found to be less damaging to underlying device layers. A heating step may optionally follow such deposition processes, e.g., to improve conductivity of the deposited layer. In some embodiments, the operating pressure of the metal oxide deposition chamber is greater than 0.01 mBar. In some embodiments, the operating pressure of the metal oxide deposition chamber is less than 200 mBar. In some embodiments, the operating pressure of the reduced pressure material coating station, and in particular a reduced pressure metal oxide deposition chamber, is in a range of from 0.01 to 200 mBar, including a range of 0.01 to 0.1 mBar, alternatively 0.1-0.2 mBar, alternatively 0.2-0.5 mBar, alternatively 0.5-1.0 mBar, alternatively 1-2 mBar, alternatively 2-5 mBar, alternatively 5-10 mBar, alternatively 10-20 mBar, alternatively 20-50 mBar, alternatively 50-100 mBar, alternatively 100-200 mBar, or any combination of ranges thereof.

Following application of the metal oxide in the metal oxide deposition chamber, the substrate 297 may traverse slot 231-4 and move to exit chamber 234. Exit chamber 234 may have a similar function as entry chamber 232 with respect to stepping the pressure down from the ambient outside of the RPMO deposition tool at the substrate exit. In particular, exit chamber 234 may optionally include two or more sub chambers 234b and 234a and a slot 231-5 through which the substrate may traverse from sub chamber 234b to 234a. Exit chamber 234 is at a reduced pressure relative to outside of the RPMO deposition station. In some cases, sub chamber 234a may be at a reduced pressure relative to outside the RPMO tool (which may be ambient pressure), and sub chamber 234b may be at a pressure that is reduced relative to sub chamber 232b. That is, the pressure may step up as the substrate traverses through the sub chambers 234b and 234a and finally through exit slot 231-6. Each sub chamber may have its own vacuum pump, e.g., vacuum pump 236-4 for sub chamber 234b and vacuum pump 236-5 for sub chamber 234a.

FIG. 4B is a cross-sectional schematic of a non-limiting example of a splice traversing a slot according to some embodiments. Slot 231 may represent any of the slots of the RPMO deposition station discussed with respect to FIG. 4A. Slot 231 may be formed from a wall 237 and have a slot height 231H. In constructing the RPMO deposition station, the anticipated splice thickness T_{S} must be accounted for. In particular, the slot height needs to be at least as great or greater than the splice thickness. In some cases, the slot height should be at least 1.01× larger than the splice thickness. alternatively at least 1.02×, 1.05×, 1.1×, 1.2×, 1.3×, 1.4×, 1.5×, 1.7×, 2×, or 3× larger. However, if the slot height is too large relative to splice thickness, as in particular too large relative to the substrate thickness away from the splice, it can become difficult to attain the desired pressure in the RPMO deposition station, in particular, in the metal oxide deposition chamber 235. The cost and energy consumption of many vacuum pumps may become probative if the slot is too high. In some embodiments, the slot height is less than 5× the substrate thickness away from the splice, alternatively less than 4×, 3×, or 2× the substrate thickness away from the splice. In some embodiments the ratio of slot height to splice thickness is in a range of 1.05-1.1, alternatively in a range of 1.1-1.2, alternatively in a range of 1.2-1.3, alternatively in a range of 1.3-1.5, alternatively in a range of 1.5-1.7, alternatively in a range of 1.7-2.0, alternatively in a range of 2.0-2.5, alternatively in a range of 2.5-3.0, or any combination of ranges thereof, while the ratio of slot height to the substrate thickness away from the splice is in a range of 1.05-2.0, alternatively in a range of 2.0-3.0, alternatively in a range of 3.0-4.0, alternatively in a range of 4.0-5.0, or any combination of ranges thereof. In preferred embodiments, the ratio of slot height to splice thickness may be in a range of 1.05-2.0, while the ratio of slot height to the substrate thickness away from the splice may be in a range of 1.05-4.0, alternatively in a range of 1.5-4.0.

The slots of the RPMO deposition station must also be at least as wide as the substrate width. The open area of a slot should be at least as great or greater than the corresponding cross-sectional area of a splice traversing the open area of a slot. In some cases, the ratio of the open area of the slot to the cross sectional area of the splice is in a range of 1.05-1.1, alternatively in a range of 1.1-1.2, alternatively in a range of 1.2-1.3, alternatively in a range of 1.3-1.5, alternatively in a range of 1.5-1.7, alternatively in a range of 1.7-2.0, alternatively in a range of 2.0-2.5, alternatively in a range of 2.5-3.0, or any combination of ranges thereof.

In some embodiments, the edges of slot 231 may be rounded or coated with a soft material to reduce the likelihood of damage to the substrate or coated layers. In some embodiments, at least the top surface of the substrate structure (where deposition of active materials occurs) does not touch the wall 237 when passing through the slot. In some cases, the bottom of the substrate does not touch the wall when passing through the slot, but in other cases it may. In some embodiments (not shown), wall 237 may include a roller at the bottom of the slot 231 that may interface with the bottom of the substrate. Not shown, other rollers may be provided near one or both sides of the slot to stabilize the substrate from possible air flow currents or turbulence that may be caused by the pressure change.

In some embodiments, the slot may be an adjustable slot. FIG. 4C is a cross-sectional schematic of a non-limiting example of an adjustable slot according to some embodiments. FIG. 4C is similar to FIG. 4B and for clarity some of the features are not labelled, but their identities are self-evident from the previous discussion and FIG. 4B. Adjustable slot 231c may be formed by including upper and lower shutters 238u and 238l, respectively. The shutters can be moved up and down manually or automatically (e.g., using servos, motors, magnets, springs, etc.). In some cases, the adjustable slot 231c may be set to a first, low height position when just the substrate is traversing and then reset to a second, higher height position when a splice is traversing. In some embodiments a sensor may be used to detect the presence of a splice entering a slot. In such embodiments employing an adjustable slot, both the ratio of slot height to the splice thickness and the ratio of the slot height to the substrate thickness away from the splice can be minimized within the above listed ratios (e.g., within preferred ratios of from 1.05-2.0) for times when both the splice and the substrate away from the splice are traversing through a slot.

In some cases, the adjustable slot may include one or more rollers. FIG. 4D is a cross-sectional schematic of a non-limiting example of an adjustable slot with rollers according to some embodiments. FIG. 4D may be generally similar to FIG. 4C except that upper and lower shutters further include a roller 239u and 2391, respectively. These rollers may be formed of a relatively hard material as previously described. Unlike compressible nip rollers (typically made of a soft roller material), the design of FIG. 4D where the slot (space between the rollers) is adjustable may be less prone to induce sheer forces that could damage coatings on the substrate. In some embodiments, just the lower shutter may include a roller.

### SALD Station(s)

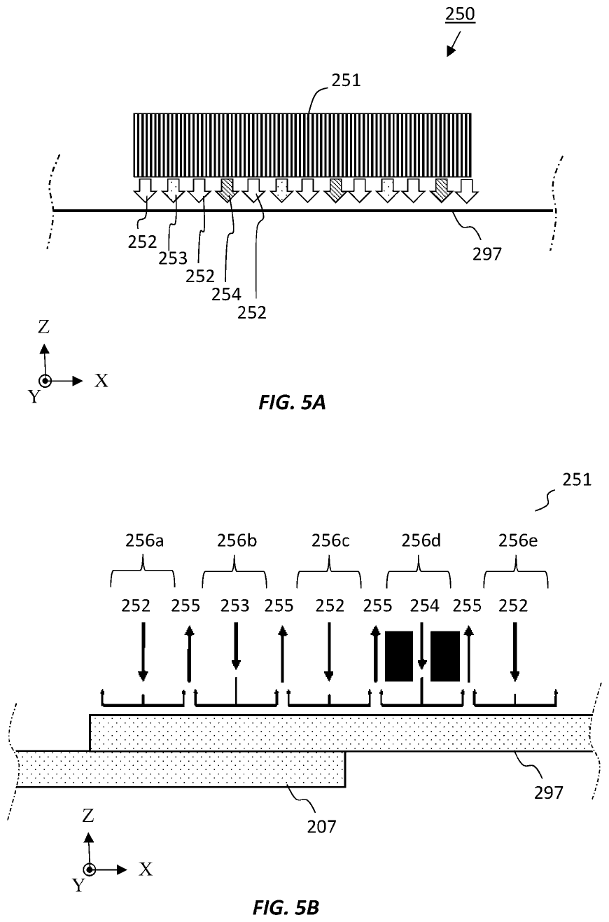

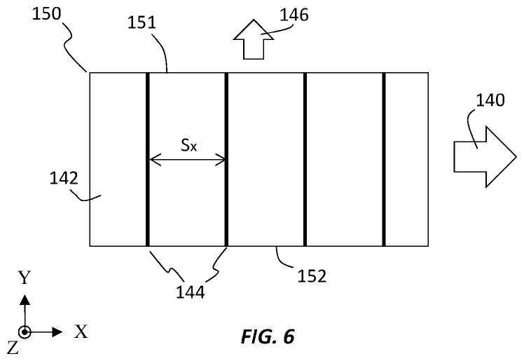

The compatibility of the splice with any SALD stations also needs consideration, e.g., with SALD-PL deposition station 250. Although SALD may be used to deposit a passivation layer as mentioned with respect to FIG. 2, SALD may instead, or in addition, be used to deposit a conducting layer, a carrier transport layer, or some other layer useful in the PV structure. FIG. 5A is a schematic cross-sectional view of an SALD station according to some embodiments. In some embodiments, the SALD station may include an atmospheric pressure SALD tool 251 which is compatible with roll-to-roll coating and may not need reduced pressure environment to operate. For example, the SALD tool may be similar to those described in U.S. Pat. No. 7,413,982, which is incorporated herein by reference for all purposes, but other designs may be used. In some cases, SALD tool 251 may include a gas manifold that applies a spatially alternating series of inert and reactive gasses. FIG. 5B is a closeup cross-sectional view of the manifold also illustrating an overlap splice about to traverse the area. For example, the manifold may include a first gas applicator structure 256a to apply an inert gas 252 such as nitrogen or argon. This may be followed by a second gas applicator structure 256b to apply a first reactive precursor gas 253. This may be followed by a third gas applicator structure 256c to apply inert gas 252. This may be followed by a fourth gas applicator structure 256d to apply a second reactive precursor gas 254. This may be followed by a fifth gas applicator structure 256e to apply inert gas 252. Additional gas applicator structures may be present downstream to build up the ALD layer thickness as the substrate structure traverses the SALD tool. The applied gasses may be removed 255 through vacuum ports provided between each gas applicator structure. A large number of precursor gas combinations are known in the art for depositing a wide variety of materials for use as a passivation layer, a conducting layer, or a carrier transport layer. A few non-limiting examples of volatile reactive precursors for forming metal compounds may include metal alkyl compounds (e.g., Al(CH₃)₃), metal alkoxides (e.g., Ti(OiPr)₄), and metal halides (e.g., ZrCl₄). Such metal compounds may be reacted with, for example, water, oxygen, ozone, or ammonia to forming the desired layer. In some preferred embodiments, the precursors have a vapor pressure and reactivity such that SALD can be carried out at temperature at or below 120° C., alternatively at or below 100° C., alternatively at or below 80° C. In some cases, a layer applied by SALD may uniformly follow the contours of the underlying structure (i.e., provide a conformal coating).

Maintaining a certain distance between the manifold and the surface of the substrate structure can be important for proper formation of the desired layer. In some cases, the inert gas 252 may act as a gas bearing that helps maintain such spacing. In some embodiments, the manifold-surface spacing is controlled in part by web handling structures, e.g., rollers that may be adjustable upwards or downwards. The presence of a splice can create challenges when using SALD. In FIG. 5B, in some embodiments, it may be desirable when using an overlapping splice to have the second substrate 207 underneath the first substrate 297 to reduce the chances of the second substate catching on the manifold which could rip the splice or damage the SALD equipment. In FIG. 5B, it may be that the splice thickness is thin enough that SALD will continue to work properly as substrate 207 moves under the manifold 251. That is, the manifold-surface spacing may increase (at least temporarily), but not so much that the SALD deposition becomes ineffective. In some embodiments, to further minimize manifold-surface spacing variations when the roll-to-roll manufacturing system includes SALD, use of splicing technologies as described above which minimizes increase in splice thickness relative to substrate thickness away from the splice, and in particular wherein the splice thickness is less than or equal to 2 times the substrate thickness away from the splice, alternatively less than or equal to 1.5 times the substrate thickness away from the splice, alternatively within 10% of the substrate thickness away from the splice, such as by use of a butt splice, may be preferred.

### Metal Lines and Patterned Metal Station(s)

There is no particular limitation on the metal material that may be used for the patterned metal lines. In some embodiments, the metal lines may include silver or copper, or alloys containing one or both of these metals. In some cases, other metals may be suitable including, but not limited to, gold, aluminum, molybdenum, tungsten, zinc, nickel, iron, tin, palladium, platinum, titanium, and alloys containing one or more of these metals. In some embodiments, the metal lines may be formed of a metal material having a conductivity of at least 105 S/m.

In some embodiments, metal lines may be formed by printing at a patterned metal station, e.g., PM1 or PM2. In some embodiments, printing at PM1 may involve patterned application of an electroless metallization catalyst (e.g., palladium) followed by contact with an electroless plating solution (e.g., copper or nickel). In some preferred embodiments, metal lines may be printed at PM1 or PM2 using a metal-containing fluid mixture or “metal ink” (e.g., a suspension, slurry, paste, or the like). In some cases, printing metal lines may be performed by flexographic printing, inkjet printing, gravure printing, imprinting, or some other printing technology. The printed metal lines may in some cases be followed by a heat treatment to drive off solvent or cause metal particles to fuse or sinter, which can increase the metal conductivity. Heat treatments may include an oven, IR heaters, flashlamps, heated rollers (with or without pressure), or the like. U.S. Pat. No. 8,907,258, incorporated herein by reference for all purposes, discloses a non-limiting example of a pulsed radiation apparatus that may be suitable for metal particle sintering in a roll-to-roll manner. In some cases, a printed metal ink may be subjected to a secondary chemical treatment such as a reducing agent. The metal ink may include metal particulates of various shapes and sizes (e.g., spherical, oblong, nanoparticles, nanowires) in an appropriate liquid carrier and may further include other agents such as binders, surfactants, or the like. A few non-limiting examples of metal inks may include those disclosed in US20220025200, which is incorporated herein by reference for all purposes. In some embodiments, a surface receiving the metal ink may first be treated to modify its surface energy, e.g., by corona discharge, a plasma, UV/ozone, or a chemical treatment. Modification of this surface energy can in some cases be used to control the shape, dimension, and/or adhesion of the deposited metal ink.

The particular set of metal materials and patterning methods may be different for a bottom set of metal lines relative to a top set of metal lines. For example, if forming a bottom set of metal lines at PM1, the substrate may have a relatively wide tolerance for ink solvents, plating, photolithography, heat treatments, surface treatments, and the like. However, if forming a top set of metal lines at PM2, the top conducting layer and underlying charge transport and perovskite layers may have a lower tolerance for these materials and treatments. In some embodiments, a set of top metal lines may be preferably formed using technology other than photolithography or plating, e.g., printing such as flexographic printing.

### Metal Line Patterns

There is no particular limitation on the pattern or dimensions of the metal lines, but it is useful to describe at least some of these properties and options. FIG. 6 is a top view of a non-limiting example of a set of metal lines according to some embodiments. Surface 142 may correspond to the surface of a substrate when the set of metal lines 144 represents the bottom set of metal lines (e.g., 103 in FIG. 1). Alternatively, surface 142 may correspond to the upper portion of the second conducting layer when the set of metal lines 144 represents the top set of metal lines (e.g., 109 in FIG. 1). The metal lines may be provided by roll-to-roll coating as discussed, and arrow 140 may correspond to the direction of web conveyance. The set of metal lines may be characterized by an average spacing Sₓ. In some preferred embodiments, the metal lines may be substantially parallel to each other and uniformly spaced. The metal lines may be substantially parallel to the Y axis in FIG. 6. When using roll-to-roll coating, such metal lines may be advantageously provided having a direction substantially orthogonal to the web conveyance direction, e.g., when using flexographic printing methods for the metal lines. In some cases, however, the metal lines may be provided at a different angle, or at various angles. Similarly, in some cases, the spacing may not be uniform. Although shown as straight lines, the metal lines could include some curvature or a zig-zag pattern. In some cases, a set of metal lines may include a crosshatch grid pattern.

In the operation of a finished PV cell after manufacturing, positive or negative charges may generally flow in a direction 146, substantially parallel to the set of metal lines, to a first edge 151 of PV cell 150 where the current may be collected by a bus line or transferred in series to an adjacent cell (not shown). Although not shown, the opposite charges may flow in the direction opposite of arrow 146 to the second edge 152 of cell 150 to be collected by a bus line or transferred in series to an adjacent cell.

Referring again to FIG. 1, a metal line may be characterized in cross section by a height (or thickness, e.g., in a Z axis) and width. Height and width may be measured at a particular point or may be reported as an average height and average width along a metal line. In some embodiments, the height or width may vary along the length of a metal line. A metal line cross-section may take on a variety of shapes and sizes. For example, a metal line may have a hemispherical shape in cross-section. Alternatively, a metal line may have a square, rectangular, trapezoidal, or some other polygonal shape in cross section.

In some embodiments, a set of metal lines (top or bottom) occupies less than 15% of the active cell surface area, preferably less than 10%, more preferably less than 5%. In some cases, a set of metal lines occupies an active cell surface area in a range of 0.5% to 10%, or alternatively 1 to 5%. In some cases, the average spacing of the metal lines is in a range of 0.1 to 2.0 mm. In some cases, a ratio of average spacing of the metal lines to the average width of the metal lines is in a range of 10 to 100. In some embodiments, the average width of the metal lines of a set of metal lines is less than 40 μm, preferably less than 30 μm. In some embodiments, the average width of the metal lines of the top or bottom set of metal lines may be in a range of 1 to 30 μm, alternatively 2 to 25 μm. In some embodiments, the average height of the metal lines of a set of metal lines is at least 50 nm, preferably at least 100 nm.

In some embodiments, when both the top and bottom electrodes use transparent composite conductors, the bottom set of metal lines may be different in some way relative to the top set of metal lines, besides the location in the photovoltaic stack. In some cases, this difference may be with respect to the metal material and/or at least one physical dimension (spacing, height, width, line direction, any ratios thereof, or the like). With respect to physical dimensions, such difference may be at least 5%, alternatively at least 10%, alternatively at least 20%, or alternatively at least 50%. For example, the spacings between at top set of metal lines may be different than the spacings of a bottom set of metal lines. In some embodiments, the average width of a bottom set of metal lines may be in a range of 15 to 40 μm, whereas an average width of a top set of metal lines may be in a range of 2 to 20 μm. In some printing embodiments, the width of the metal lines may in part be controlled by adjusting the surface energy of the surface on which they are printed. For example, matching a surface energy to an ink may allow for more spreading of the ink and produce wider lines. A mismatch in surface energy may reduce the amount of ink spreading and produce narrower lines.

In some embodiments, an average height of a set of bottom metal lines may be less than 300 nm, preferably less than 200 nm, more preferably less than 150 nm. For example, in some cases the average height of a set of bottom metal lines may be in a range of about 20-200 nm, alternatively in a range of 50-150 nm. In some cases, a set of top metal lines may have a height of greater than 50 nm, alternatively greater than 100 nm, alternatively greater than 200 nm, or alternatively greater than 500 nm. For example, in some cases an average a set of top metal lines may be in a range of 200-1500 nm. In some embodiments when printing a set of top metal lines, it may be difficult to fully sinter the metal without damaging the underlying perovskite or other layers. As such, the intrinsic resistivity of the metal line material may be higher than for a fully sintered metal line material. In such cases it may be preferred to deposit a thicker metal line to compensate. In some embodiments, the bottom set of metal lines may include silver and the top set of metal lines may include copper.

### Composite Conductors

The transparency of a composite conductor depends on the width and spacing of the metal lines (which are mostly opaque), the transparency of the conducting layer, and may also depend in part on the layers adjacent the composite conductors, e.g., on their index of refraction. Metal lines have been generally discussed above. Below is a further discussion of methods and materials for forming a transparent conducting layer usually with respect to composite conductors, but it should be appreciated that the materials and method for forming the transparent conducting layer can generally be applied to any transparent electrodes that do not include the metal lines.

### Transparent Conducting Layers

In some embodiments, a transparent conducting layer or transparent electrode may include a conductive polymer material such as PEDOT:PSS, a poly(pyrrole), a polyaniline, a polyphenylene, or a poly(acetylene). Conductive polymers may be applied by a coating from a suspension or solution, e.g., using any of the coating methods described herein with respect to the perovskite absorbing layer. After coating, the conducting layer may optionally be subjected to heating or some other drying step to drive off solvent or otherwise improve conductivity properties of the conductive polymer.

In some embodiments, a transparent conducting layer or transparent electrode may include high aspect ratio metal nanowires (e.g., silver nanowires) or carbon nanotubes. Such materials may be coated from a dispersion (optionally with a binder) at a density sufficient to form an interconnected, conductive mesh, but low enough to achieve a desired transparency. After coating, the conducting layer may optionally be subjected to heating or some other drying step to drive off solvent or otherwise improve conductivity properties of the metal nanowires or carbon nanotubes.

In some preferred embodiments, a transparent conducting layer or transparent electrode may include doped or undoped metal oxides such as tin oxide (e.g., doped with indium or fluorine), molybdenum oxide, and zinc oxide (e.g., doped with aluminum). Such metal oxides are sometimes referred to as transparent conductive oxides (TCOs). TCOs may in some cases be coated from a suspension of metal oxide particles or formed from a sol-gel precursor solution, typically followed by a heating step to drive off solvent and anneal or sinter the metal oxide particles. In some preferred embodiments, a TCO may be deposited using an RPMO tool as already discussed. A heating step may optionally follow such dry deposition processes, e.g., to improve conductivity of the deposited layer.

In some preferred embodiments, the conducting layer may be interposed between the metal line and a charge carrier layer. Such an arrangement has been found to reduce migration of metal and/or halide ions into the active portion of the perovskite photovoltaic structure. Such migration may cause degradation of performance over time. In some particularly preferred embodiments, the interposing conducting layer includes a TCO as described previously, e.g., indium-doped tin oxide (ITO) or aluminum doped zinc oxide (AZO). The TCO conducting layer may act as a barrier layer to diffusion of the metal and/or halide ions.

In some embodiments, the applied transparent conducting layer or transparent electrode may have an intrinsic sheet resistance (i.e., as measured in the absence of metal lines) of less than 1000 Ω/square, preferably less than 300 Ω/square. In some embodiments, the conducting layer may have a % T within a target wavelength range of at least 80%, alternatively at least 90%, at least 95%, or at least 97% (as measured in the absence of the metal lines).

The thickness of a conducting layer or transparent electrode depends in part on the electrical and optical properties of the selected material and may also depend on the deposition method. In some embodiments, the conducting layer may have a thickness of less than 200 nm, alternatively less than 100 nm, alternatively less than 50 nm, alternatively less than 20 nm, or alternatively less than 10 nm. In some embodiments, the conducting layer may be an aerosol-applied TCO having an average thickness in a range of 30 nm to 100 nm. When a conducting layer is applied over a set of metal lines, the average thickness may correspond to areas between the metal lines. When applied over metal lines, it is desirable in many cases that the conducting layer also substantially covers the metal lines to help ensure electrical continuity and prevent or reduce migration of metal ions into the active layers. In some cases, a surface energy modifying treatment may be applied to the substrate and a bottom set of metal lines to assist in adhesion and/or uniform deposition of the first conducting layer over both the substrate and the metal lines.

### Substrate

The substrate is generally electrically insulating and may be formed from any suitable flexible material(s) suitable for roll-to-roll processing. For use with transparent bottom electrodes, the substrate may be formed from any suitable transparent flexible material(s), such as a glass, a polymer (plastic), or a combination of different materials. Some non-limiting examples of transparent substrates may include thin flexible glass such as Corning® Willow® Glass, a polyethylene terephthalate (PET) (which may optionally be a heat-stabilized PET), a polyethylene naphthalate (PEN), a polycarbonate (PC), a polysulfone (PS), a polyether sulfone (PES), a polyamide, p-nitrophenylbutyrate (PNB), a polyetherketone (PEEK), a polyetherimide (PEI), a polyarylate (PAR), a polyvinyl acetate, a polyimide, a cyclic olefin polymer (COP), a cellulose triacetate (TAC), a polyacrylate, or an epoxide. For some applications, some particularly useful transparent substrates include flexible glass, PET and heat-stabilized PET. The substrate may optionally include multiple materials or have a multilayer structure. The substrate may include a surface treatment to modify the surface energy for improved coating quality and/or adhesion of subsequent layers. Some non-limiting examples of surface treatments include corona discharge, ozone (created, for example, with ultraviolet radiation), and plasma. Surface treatment devices may operate in ambient air, conditioned air (where temperature and relative humidity are controlled), oxygen, or inert gas such as nitrogen or argon. In some embodiments, a surface-modifying treatment may involve a wet chemical treatment or even an additional surface layer deposited by a wet- or dry-coating method. In some cases, a surface layer may be referred to as a primer layer. In some cases, the substrate may act as a water vapor or oxygen barrier, e.g., through choice of substrate material or by addition of one or more barrier layers, for example aluminum.

Note that by “flexible” it is generally meant that the material can undergo some shape changes at least in one dimension (e.g., orthogonal to web direction so it can bend around rollers or the like) in response to some force or stress without significant damage. In some cases, flexibility of a substrate or material may be measured by its bend radius, which is the minimum radius that it can be bent without functionally damaging it. In some embodiments, a flexible support may have a bend radius of less than 25 cm, alternatively less than 15 cm, 10 cm, 5 cm, 4 cm, 3 cm, 2 cm, or 1 cm. In some preferred embodiments, a flexible substrate may have a bend radius of less than 10 cm.

In some preferred embodiments, a flexible substrate is suitable for roll-to-roll manufacturing and may have a thickness of less than about 350 μm if it is flexible glass (e.g., a thickness in a range of 50 to 350 μm), or alternatively less than about 250 μm if it is a flexible plastic (e.g., a thickness in a range of 20 to 250 μm).

In cases where the bottom electrode does not need to be transparent, the substrate may optionally include or be a flexible metal foil which may also act as the bottom electrode.

### First and Second Carrier Transport Layers

The first and second carrier transport layers may be deposited at carrier transport layer deposition stations 240 and 260, respectively. The deposition methods should be compatible with roll-to-roll manufacturing. As mentioned, one carrier transport layer includes a hole transporting material, and the other carrier transport layer includes an electron transporting material. A carrier transport material that includes a hole transporting material may be referred to as a hole transport layer. In addition to transporting holes, a hole transporting material may also effectively block the transport of electrons. A carrier transport material that includes an electron transporting material may be referred to as an electron transport layer. In addition to transporting electrons, an electron transporting material may also effectively block the transport of holes. In some embodiments, a carrier transport layer may include multiple layers of materials. A non-limiting example of a multilayer charge transport layer may include embodiments where one sublayer is especially for transporting the desired charge and another sublayer especially for blocking the opposite charge. In some cases, a blocking sublayer may be adjacent to the perovskite blocking layer. The thickness of a carrier transport layer depends in part on the properties of the overall photovoltaic stack, but in some embodiments, may have an average thickness in a range of 10's to 100's of nanometers.

Some non-limiting examples of hole-transporting materials may include a poly(triaryl amine) (e.g., poly [bis(4-phenyl) (2,4,6-trimethylphenyl)amine]), a poly-(N-vinyl carbazole), PEDOT complex, a poly(3-hexylthiophene), spiro-MeOTAD (also known as N²,N²,N²′,N²′,N⁷,N⁷,N⁷,NT-octakis (4-methoxyphenyl)-9,9′-spirobi[9H-fluorene]-2,2′,7,7′-tetramine), poly-TPD, EH44, certain metal oxides (e.g. nickel oxide, molybdenum oxide, and vanadium oxide, any of which may optionally be doped), copper thiocyanate and copper iodide, and certain self-assembled monolayers (e.g. 2-(9H-Carbazol-9-yl)ethyl]phosphonic acid)

Some non-limiting examples of electron-transporting materials may include fullerenes, (e.g., phenyl-C61-butyric acid methyl ester (PCBM) and fullerene-C60), bathocuproine (BCP), TPBI, PFN, PC₇₁BM, ICBA, graphene, reduced graphene oxide, certain metal oxides (e.g., tin oxide, zinc oxide, cerium oxide, and TiO₂, any of which may optionally be doped).

Depending in part upon the particular material, a carrier transport layer may in some cases be deposited by a dry deposition process, e.g., using a reduced pressure material deposition tool or SALD so long as it is compatible with roll-to-roll manufacturing.

In some embodiments, a carrier transport layer may be deposited by a coating process that does not require reduced pressure. Some non-limiting examples of coating processes may include gravure, slot die, spray, dip coat, inkjet, flexographic, rod, or blade coating methods. In some cases, a coating process may be followed by a thermal treatment to drive off solvent, anneal the carrier transport material, or the like.

In some embodiments, a carrier transport layer may be deposited by transfer of the carrier transport material from a donor sheet, e.g., by application of heat or some other stimulus to release it from the donor sheet with adherent transfer to the appropriate device layer or substrate.

### Perovskite Absorbing Layer

The perovskite absorbing layer may be deposited at stations 245. The deposition methods should be compatible with roll-to-roll manufacturing. Perovskite materials and methods for forming perovskite absorbing layers may be as described in U.S. Pat. No. 11,108,007, U.S. U.S. Pat. No. 11,342,130, U.S. Application No. 2020/0377532, and U.S. Application Publication No. 2022/0238807, the entire contents of which are incorporated herein by reference. In some embodiments, a perovskite absorbing layer may be coated from a fluid mixture, which may be referred to as a perovskite solution. Any coating method suitable for coating a fluid mixture may be used including, but not limited to, gravure, slot die, spray, dip coat, inkjet, flexographic, rod, or blade coating methods.

The term “perovskite solution” refers to a solution or colloidal suspension that can be used to generate a continuous layer of organic-inorganic hybrid perovskite material, or a fully inorganic perovskite material, (the perovskite layer), e.g., one with an ABX₃ crystal lattice where ‘A’ and ‘B’ are two cations of very different sizes, and X is an anion that coordinates to both cations. A perovskite solution typically includes an appropriate set of perovskite precursor materials and one or more solvents in which the precursor material is dissolved or suspended. A perovskite solution may also contain additives, e.g., to aid in crystal growth or to modify crystal properties or for some other purpose. A perovskite precursor material is typically an ionic species where at least one of its constituents becomes incorporated into the final perovskite layer ABX₃ crystal lattice. Organic perovskite precursor materials are materials whose cation contains carbon atoms while inorganic perovskite precursor materials are materials whose cation contains metal but does not contain carbon.

When the perovskite solution dries, perovskite crystals or an intermediate precursor phase for hybrid perovskite crystals (intermediate phase) form. The intermediate phase is a crystal, adduct, or mesophase that is not the desired final crystal lattice, which is ABX₃. The intermediate phase, if present, may be converted to the desired final crystal lattice by annealing. In some cases, annealing or other heating methods may include the use of heated nip rollers, optionally under nitrogen.

Some non-limiting examples of inorganic perovskite precursor materials for making perovskite solutions may include lead (II) iodide, lead (II) acetate, lead (II) acetate trihydrate, lead (II) chloride, lead (II) bromide, lead nitrate, lead thiocyanate, tin (II) iodide, rubidium halide, potassium halide, tin halide or other tin salts, and cesium halide. In some cases, the halide may include iodide. Some non-limiting examples of organic perovskite precursor materials for making perovskite solutions may include methylammonium iodide, methylammonium bromide, methylammonium chloride, methylammonium acetate, formamidinium bromide, and formamidinium iodide. To produce a high-performance perovskite device, it is generally preferred in some cases that the organic perovskite precursor material has a purity greater than 99 percent by weight and the inorganic perovskite precursor has a purity greater than 99.9 percent by weight. The inorganic perovskite precursor material contains a metal cation, and in some preferred embodiments, the metal cation is lead. In some preferred embodiment, the molar ratio of organic perovskite precursor material to inorganic perovskite precursor material may be in a range of one to three.

In some cases, a perovskite solution may be formulated using a large proportion of a low boiling point solvent (e.g., at least 50 wt. % of total solvent, preferably at least 75 wt. % of total solvent, more preferably at least 90 wt. % of total solvent). In some embodiments, a low boiling point solvent is one having a boiling point of less than 150° C., or preferably less than 135° C. Such proportions may assist or enable high speed production of a uniform perovskite layer. Using an appropriate drying method, a low boiling point solvent can be made to evaporate quickly from the perovskite solution after deposition on a substrate thus minimizing movement of the crystals that form as the perovskite solution dries. Solvents that do not strongly coordinate with the perovskite precursors further enable short annealing times. Short annealing times are desirable because they enable higher production speeds. Alcohol-based solvents have been identified that do not strongly coordinate with the perovskite precursors, can provide the proper solubility of the inorganic precursors, and have been shown to produce a perovskite solution that can be stable for use in high volume manufacturing of perovskite layers and photovoltaic devices. Some non-limiting examples of alcohol-based solvents suitable for use at high proportions in the perovskite solution may include 2-methoxyethanol, 2-ethoxyethanol, 2-butoxyethanol, 2-isopropoxyethanol, methanol, propanol, butanol, and ethanol. Mixtures of solvents are envisioned for use in the perovskite solution to tune the evaporation profile to further optimize the drying process. Some non-limiting examples of suitable solvent additives useful for modifying evaporation rate of the solvent may include dimethylformamide, acetonitrile, dimethyl sulfoxide, N-methyl-2-pyrrolidone, dimethylacetamide, gamma-butyrolactone, phenoxyethanol, acetic acid, and urea.

In some preferred embodiments, a perovskite solution may be formulated with greater than 30 wt. % of solvent (e.g., 30-82 wt. %) and at least 18 wt. % of solids (e.g., 18-70 wt. %, preferably 25-60 wt. %, or 30-45 wt. %), where the total solids concentration of the perovskite solution is in a range of 30-70% by weight of its saturation concentration at the provided solution temperature. In some preferred embodiments, a solution temperature may be in a range of 20-50° C. In some preferred embodiments, the solvent is an alcohol and has a boiling point less than 135° C. In some preferred embodiments, the solvent is 2-methoxyethanol, which has a boiling point of 125° C. In some embodiments, such formulations may provide perovskite solutions that are stable at convenient handling and storage temperatures (e.g., in a range of 20-50° C., and in particular, room temperatures in a range of 20-25° C.), and which can be used to manufacture uniform perovskite layers at high speed, thereby enabling low-cost production of high efficiency solar cells with low equipment costs.

Although uniform perovskite layers have been made at high production speeds with the above formulations, it has sometimes been found that the time required for the perovskite solution to form homogeneous nuclei and grow may be longer than the time required to evaporate the low boiling point solvent in such a way as to produce a uniform perovskite layer. A uniform perovskite layer with optimum sized crystals is desired to make perovskite devices with high photovoltaic energy output. Addition of a crystal growth modifier added to a perovskite solution having a low boiling point solvent has been found to improve the performance of perovskite photovoltaic devices. A crystal growth modifier refers to an additive that either alters the amount of time for homogeneous crystal growth or alters the rate of homogeneous crystal growth when drying a perovskite solution. Some non-limiting examples of crystal growth modifiers that are especially useful in perovskite solutions for making high performance perovskite layers include dimethyl sulfoxide, N-methyl-2-pyrrolidone, gamma-butyrolactone, 1,8-diiodooctane, N-cyclohexyl-2-pyrrolidone, water, dimethylacetamide, acetic acid, cyclohexanone, alkyl diamines, and hydrogen iodide. In some preferred embodiments, the concentration of a crystal growth modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

Another additive for a perovskite solution that may improve the performance of perovskite devices is a crystal grain boundary modifier. A crystal grain boundary modifier refers to an additive that improves the quality of the grain boundary, for example, be altering the electrical properties of the perovskite crystal grain boundary or reducing trap states at perovskite crystal grain boundary interfaces. Some non-limiting examples of crystal grain boundary modifiers that can be particularly useful in perovskite solutions for making high performance perovskite layers include choline chloride, phenethylamine, hexylamine, 1-α-phosphatidylcholine, polyethylene glycol sorbitan monostearate, sodium dodecyl sulfate, Poly(methyl methacrylate), Polyethylene glycol, pyridine, thiophene, ethylene carbonate, propylene carbonate, fullerenes, poly(propylene carbonate), and didodecyldimethylammonium bromide. A preferred concentration of crystal grain boundary modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

### EXAMPLES

The various embodiments and features described herein may be particularly useful with regard to continuous roll-to-roll manufacturing systems and methods for making photovoltaic structures, wherein the method comprises:
a) conveying at ambient pressure a continuous flexible substrate to a first carrier transport layer deposition station and depositing a first carrier transport solution to form a first carrier transport layer on the continuous flexible substrate;
b) conveying the continuous flexible substrate to a perovskite deposition station and depositing a perovskite solution to form a perovskite photoactive absorber layer over the first carrier transport layer;
c) conveying the continuous flexible substrate to a second carrier transport layer deposition station and depositing a second carrier transport solution to form a second carrier transport layer over the perovskite photoactive absorber layer;
d) conveying the continuous flexible substrate to a metal deposition station for printing a metal particle solution over the second carrier transport layer to form a patterned top set of metal lines;
e) conveying the continuous flexible substrate to a reduced pressure deposition station, depositing dry metal oxide aerosol particles to from a transparent top conducting layer over the second carrier transport layer, then conveying the continuous flexible substrate to an ambient pressure environment;
f) conveying the continuous flexible substrate to a winding station to form a take up roll having solution deposited layers formed in an ambient environment and at least one dry deposited layer formed in a reduced pressure environment;
   wherein the continuous flexible substrate extends continuously from the dispensing roll to the take up roll.

In such specific system, the following further preferred features may specifically be employed individually or in combinations thereof:
i). While above is preferred, the top set of metal lines can be above or below the transparent top conducting layer;
ii) The continuous flexible substrate may comprise a conducting surface prior to conveyance to the first carrier transport layer deposition station a). This can be an opaque metal layer (such as aluminum or copper), or can be a transparent layer as described below in iii and iv;
iii). Prior to conveyance to the first carrier transport layer deposition station a), the continuous flexible substrate may be conveyed to a metal deposition station for printing a metal particle solution over the continuous flexible substrate to form a patterned bottom set of metal lines;
iv). Prior to conveyance to the first carrier transport layer deposition station a), the continuous flexible substrate may be conveyed to a reduced pressure deposition station where dry metal oxide aerosol particles are deposited to form a transparent bottom conducting layer over the continuous flexible substrate, and then the continuous flexible substrate may be conveyed to an ambient pressure environment;
V) A splice may be formed at a splicing station at ambient pressure, splicing an end portion of a first PV substrate roll to a starting portion of a second PV substrate roll thereby forming a continuous substrate comprising a splice, wherein the end portion is characterized by a first substrate thickness, the starting portion is characterized by a second substrate thickness, and the splice is characterized by a splice thickness that is equal to or less than 2× the sum of first substrate thickness and the second substrate thickness;
vi) The splice may be formed in a manner that allow continuous production, that is, without interrupting the deposition of the PV layers;
vii). The continuous flexible substrate may be conveyed to a spatial atomic layer deposition (SALD) station and a metal compound layer may be deposited over the continuous flexible substrate;
viii). The continuous flexible substrate may be conveyed to one or more barrier/passivation deposition stations and one or more barrier/passivation solutions may be deposited to form one or more barrier/passivation layers;
ix). The splice may be formed by a laser to make a butt weld or formed by ultrasonic device to form a lap weld;
x). The metal lines may have a width less than 30 μm, preferably less than 20 μm;
xi) The continuous flexible substrate may be conveyed to one or more annealing stations that may comprise an IR lamp (NIR or mid IR), intense pulsed light, heated rollers, or hot air oven.

The unique use of solution coating of carrier transport layers and perovskite photoactive absorber layer in combination with patterned metal line coating and reduced pressure metal oxide layer coating for forming a transparent top electrode in a continuous roll-to-roll manufacturing system as described herein has in particular been found to advantageously result in improved manufacturability for photovoltaic structures comprising such relatively soft perovskite active layers.

Current manufacturing methods for making photovoltaic (PV) modules require expensive equipment, high energy usage, and high labor content, which all have significant contributions to the product cost. Product cost for PV modules is typically measured in cost per Watt. Some embodiments of the present disclosure may enable a PV module manufacturing process that has a much lower cost per Watt than current methods. Because of the high throughput enabled by in-line high speed roll-to-roll manufacturing, the cost contributions of labor, energy usage, and capital depreciation are minimized, and the resulting manufacturing cost is reduced to the cost of the materials used. Furthermore, the capital expenditures for a high speed roll-to-roll PV factory using equipment and methods described herein is estimated in some cases to be less than one tenth the cost of current PV manufacturing methods, allowing for a much more cost effective expansion of manufacturing capacity. Printing all the layers in an inline process has the added benefit of eliminating inventory staged between manufacturing equipment (work-in-process), lowering equipment costs by using less roll feeding and rewinding equipment, and reducing the overall factory footprint and building cost.

Since Perovskite absorbers can be solution deposited, they are suitable for high speed roll-to-roll production. However, to enable low costs manufacturing, all the layers of the PV device, including the transparent conducting layer, need to be made at high speed. A coating process that uses dry deposition of aerosol particles at reduced (but not necessarily high vacuum) pressures has been found to enable high speed deposition of a transparent conductor but is only cost effective in manufacturing when making thin layers. The use of very narrow metal lines to collect the current from the transparent conducting layer eliminates the need for a thick transparent conducting coating. Thus, the combination of printing of thin metal lines, dry deposition of a thin transparent conducting layer, and solution deposition of a perovskite absorber layer all at high speed in an inline roll-to-roll process enables low cost PV module production. Some non-limiting improvements and their advantages to this process include:
i) A reduced pressure deposition station (operating at, e.g., 0.01 to 200 mBar) can be combined with an air-to-air system for inline production. A high vacuum deposition station, on the other hand, may not be cost effective when inline due to the high vacuum pumping requirements.
ii) Dry deposition of aerosol particles in such a reduced pressure deposition station is a low energy deposition process that does not damage the Perovskite absorber. A high vacuum deposition station is a higher energy process that can damage the Perovskite absorber.
iii) The use of very thin buffer or passivation layers can improve the performance of Perovskite PV modules. Atomic layer deposition (ALD) can produce very compact conformal layers so is ideal for deposition of these layers. ALD methods are generally very slow processes but the use of SALD can be made fast enough to be put inline with the deposition of the other PV layers. The thin compact layer can also act as a barrier to diffusion of ions from the absorber stack to other layers.
iv) The impact on product cost from the cost of equipment and the cost of labor goes down as the speed of roll-to-roll production increases. Automatic splicing of the substrate increases the productivity and yield of roll-to-roll manufacturing because it allows continuous, uninterrupted operation. Reducing the thickness of the splice reduces the air loss in the air-to-air system thereby enabling smaller pumps that reduce equipment and energy costs. A butt or overlap splice can reduce the thickness of the splice compared to a taped splice.
v) The use of metal lines that are smooth with a low profile enables the subsequent deposition of the thin PV layers without defects. Thicker and rougher metal lines create defects that degrade the performance of the PV module. A thin transparent conducting layer in combination with metal lines enables larger PV cells compared to a thick transparent conducting layer with no metal lines because the metal lines enable a lower sheet resistance. The thin transparent conductor also acts as a barrier to diffusion of the metal line materials into the absorber stack.
vi) High speed in-line coating of all layers reduces the potential for degradation of individual layers that could be exposed to ambient environmental conditions during the device construction.

Extensive experimentation and innovation led to the approach disclosed herein to manufacture high performance perovskite PV modules at low cost.

Still further embodiments herein include the following enumerated embodiments.
1. A method of making a photovoltaic structure by continuous roll-to-roll manufacturing, the method including:
a) at a splicing station at ambient pressure, splicing an end portion of a first PV substrate roll to a starting portion of a second PV substrate roll thereby forming a continuous substrate including a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness; and
b) transporting the continuous substrate to a reduced-pressure material deposition station and depositing a material layer over the continuous substrate, wherein the reduced pressure material deposition station includes an entry slot and an exit slot through which the continuous substrate enters and exits the reduced pressure material deposition station, and wherein the entry and exit slots each have a slot height that is less than 3× the splice thickness.
2. The method of embodiment 1, wherein the reduced-pressure material deposition station includes a reduced-pressure metal oxide deposition station and step b) includes depositing a metal oxide layer over the continuous substrate.
3. The method of embodiment 1 or 2, wherein the splicing includes application of ultrasonic energy or application of laser energy.
4. The method according to any of embodiments 1-3, wherein the splicing includes application of a solvent or adhesive at an interface of the first and second PV substrates.
5. The method according to any of embodiments 1-4, wherein the splice is an overlap splice.
6. The method according to any of embodiments 1-4, wherein the splice is a butt splice.
7 The method according to any of embodiments 1-6, wherein the splice thickness is equal to or less than 1.5× the sum of the first substrate thickness and the second substrate thickness.
8 The method according to any of embodiments 1-6, wherein the splice thickness is equal to or less than 1.1× the sum of the first substrate thickness and the second substrate thickness.
9 The method according to any of embodiments 1-6, wherein the splice thickness is less than 1.0× the sum of the first substrate thickness and the second substrate thickness.
10. The method according to any of embodiments 1-9 wherein one or each slot height is less than 2× the splice thickness.
11. The method according to any of embodiments 1-9, wherein one or each slot height is less than 1.5× the splice thickness.
12. The method according to any of embodiments 1-11, wherein one or each slot height is at least 1.05× the splice thickness.
13. The method according to any of embodiments 1-12, wherein one or each slot is an adjustable-height slot, the method further including changing the slot height when a splice traverses the adjustable height slot.
14. The method according to any of embodiments 1-13, wherein at least one slot is characterized by an opening area and the splice traversing the at least one slot is characterized by a splice cross-sectional area, and wherein a ratio of the opening area to the splice cross sectional area is in a range of 1.05 to 3.0.
15. The method according to any of embodiments 1-14, wherein the reduced pressure material deposition station further includes:
a) an entry chamber including the entry slot for receiving the continuous substrate, wherein the entry chamber is at an average pressure less than ambient pressure;
b) a material deposition chamber adjacent to the entry chamber, wherein the material deposition chamber is at a lower average pressure than the entry chamber; and
c) an exit chamber adjacent to the material deposition chamber and opposite the entry chamber, wherein the exit chamber includes the exit slot through which the continuous substrate exits, and wherein the exit chamber is at an average pressure that is higher than the material deposition chamber and lower than ambient pressure.
16. The method according to any of embodiments 1-15, wherein the reduced pressure material deposition station deposits a transparent conducting layer that forms at least part of a photovoltaic structure electrode.
17. The method of embodiment 16, wherein the photovoltaic structure electrode is a composite conductor including the transparent conducting layer in contact with a set of patterned metal lines.
18. The method according to any of embodiments 1-17, wherein depositing the material layer in the reduced-pressure material deposition station includes aerosol deposition.
19. The method according to any of embodiments 1-18, wherein the material layer in the reduced-pressure material deposition station includes ITO or AZO.
20. The method according to any of embodiments 1-19, further including transporting the continuous substrate to a photoactive layer deposition station including at least an active absorber material coating apparatus and forming an active absorber layer over the continuous substrate by depositing and drying a liquid active absorber material mixture.
21. The method of embodiment 20, wherein the active absorber material includes a perovskite material and the active absorber layer is a perovskite absorber layer.
22. The method of embodiment 20 or 21, wherein forming the active absorber layer includes the use of a gravure cylinder, slot die deposition, anilox cylinder, offset cylinder, or flexography.
23. The method according to any of embodiments 20-22, wherein the continuous substrate is transported to the photoactive layer deposition station prior to transporting to the reduced pressure material deposition station.
24. The method according to any of embodiments 20-22, wherein the continuous substrate is transported to the photoactive layer deposition station after transporting to the reduced pressure material deposition station.
25. The method of embodiment 24, wherein the reduced pressure material deposition station is a first reduced pressure metal oxide deposition station that deposits a first metal oxide layer, the method further including transporting the continuous substrate to a second reduced pressure metal oxide deposition station and depositing a second metal oxide layer over the active absorber layer.
26. The method of embodiment 25, wherein depositing the second metal oxide layer includes aerosol deposition.
27. The method of embodiment 25 or 26, wherein the second metal oxide includes ITO or AZO.
28. The method according to any of embodiments 20-27, further including transporting the continuous substrate to a first carrier transport layer deposition station and forming a first carrier transport layer prior to the transporting to the photoactive layer station.
29. The method of embodiment 28, wherein forming the first carrier transport layer includes depositing and drying a liquid first carrier transport material mixture.
30. The method of embodiment 28 or 29, wherein forming the first carrier transport layer includes the use of a gravure cylinder, slot die deposition, anilox cylinder, offset cylinder, or flexography.
31. The method of embodiment 28, wherein forming the first carrier transport layer includes deposition from a reduced pressure material deposition tool or a spatial atomic layer deposition tool.
32. The method according to any of embodiments 20-31, further including transporting the continuous substrate to a second carrier transport layer deposition station and forming a second carrier transport layer over the active absorber layer.
33. The method of embodiment 32, wherein forming the second carrier transport layer includes depositing and drying a liquid second carrier transport material mixture.
34. The method of embodiment 32 or 33, wherein forming the second carrier transport layer includes the use of a gravure cylinder, slot die deposition, anilox cylinder, offset cylinder, or flexography.
35. The method of embodiment 32, wherein forming the second carrier transport layer includes deposition from a reduced pressure material deposition tool or spatial atomic layer deposition.
36. The method according to any of embodiments 20-35, further including transporting the continuous substrate to a first patterned metal deposition station and forming a bottom set of metal lines over the continuous substrate, wherein the material layer deposited in the reduced-pressure material deposition station is a first metal oxide deposited over and in contact with the bottom set of metal lines to form a bottom electrode.
37. The method of embodiment 36, wherein the bottom set of metal lines are formed by printing a first metal-containing ink.
38. The method of embodiment 37, wherein printing the first metal-containing ink includes flexographic printing or gravure printing.
39 The method of embodiment 37 or 38, wherein the first metal-containing ink includes silver or copper.
40. The method according to any of embodiments 20-39, further including transporting the continuous substrate to a second patterned metal deposition station and forming a top set of metal lines over the continuous substrate, wherein the top set of metal lines are deposited over and in contact with a second metal oxide layer to form a top transparent electrode.
41. The method of embodiment 40, wherein the top set of metal lines are formed by printing a second metal-containing ink.
42. The method of embodiment 41, wherein printing the second metal-containing ink includes flexographic printing or gravure printing.
43. The method of embodiment 41 or 42, wherein the second metal-containing ink includes silver.
44. The method of embodiment 41 or 42, wherein the second metal-containing ink includes copper.
45. The method according to any of embodiments 1-44, further including transporting the continuous substrate to a spatial atomic layer deposition station and depositing a passivation layer over the continuous substrate.
46. The method of embodiment 45, wherein the passivation layer is provided over and in contact with a bottom electrode.
47. The method of embodiment 46, wherein the passivation layer is provided over a photoactive layer and prior to forming a top electrode.
48. The method of according to any of embodiments 45-47, wherein the passivation layer includes a passivating metal oxide.
49. The method according to any of embodiments 1-48, wherein the photovoltaic structure includes a transparent top electrode.
50. The method of embodiment 49, wherein the photovoltaic structure includes a transparent bottom electrode.
51. The method of embodiment 49, wherein the photovoltaic structure includes a bottom electrode that is less transparent than the top electrode.
52. The method according to any of embodiments 1-51, wherein the continuous substrate is transported from one station to another at an average speed of at least 5 meters per minute.
53. The method according to any of embodiments 1-52, wherein the second substrate includes a pre-splice bottom electrode formed on the second substrate prior to splicing.
54. The method of embodiment 53, wherein the pre-splice bottom electrode includes a composite conductor structure.
55. The method of embodiment 53, wherein the pre-splice bottom electrode includes aluminum.
56. The method according to any of embodiments 1-55, wherein the first and second substrates include PET, PEN, or polycarbonate.
57. A method of making a photovoltaic structure by continuous roll-to-roll manufacturing, the method including:
a) at a splicing station at ambient pressure, splicing an end portion of a first PV substrate roll to a starting portion of a second PV substrate roll thereby forming a continuous substrate including a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness; and
b) transporting the continuous substrate to a spatial atomic layer deposition (SALD) station and depositing a metal compound layer by SALD over the continuous substrate.
58. The method of embodiment 57, wherein the splicing includes application of ultrasonic energy.
59. The method of embodiment 57 or 58, wherein the splicing includes application of laser energy.
60. The method according to any of embodiments 57-59, wherein the splicing includes application of a solvent or adhesive at an interface of the first and second PV substrates.
61. The method according to any of embodiments 57-60, wherein the splice is an overlap splice.
62. The method according to any of embodiments 57-60, wherein the splice is a butt splice.
63. The method according to any of embodiments 57-62, wherein the splice thickness is equal to or less than 1.5× the sum of the first substrate thickness and the second substrate thickness.
64. The method according to any of embodiments 57-62, wherein the splice thickness is equal to or less than 1.1× the sum of the first substrate thickness and the second substrate thickness.
65. The method according to any of embodiments 57-62, wherein the splice thickness is less than 1.0× the sum of the first substrate thickness and the second substrate thickness.
66. The method according to any of embodiments 57-62, wherein the splice thickness is within 10% of the first substrate thickness.
67. The method according to any of embodiments 57-66, wherein the metal compound layer includes a metal oxide.
68. The method according to any of embodiments 57-67, wherein the metal compound layer is electrically conductive and forms at least part of a photovoltaic structure electrode.
69. The method according to any of embodiments 57-67, wherein the metal compound layer is a passivation layer that impedes the diffusion of metal ions or halide ions or both.
70. The method according to any of embodiments 57-69, wherein the metal compound layer has a thickness of 50 nm or less, or optionally 10 nm or less, or optionally 2 nm or less.
71. The method according to any of embodiments 57-70, further including transporting the continuous substrate to a photoactive layer deposition station including at least an active absorber material coating apparatus and forming an active absorber layer over the continuous substrate by depositing and drying a liquid active absorber material mixture.
72. The method of embodiment 71, wherein the active absorber material includes a perovskite material and the active absorber layer is a perovskite absorber layer.
73. The method of embodiment 71 or 72, wherein forming the active absorber layer includes the use of a gravure cylinder, slot die deposition, anilox cylinder, offset cylinder, or flexography.
74 The method according to any of embodiments 71-73, wherein the continuous substrate is transported to the photoactive layer deposition station prior to transporting to the SALD station.
75. The method according to any of embodiments 71-73, wherein the continuous substrate is transported to the photoactive layer deposition station after transporting to the SALD station.
76. The method of embodiment 75, wherein the SALD station is a first SALD station that deposits a first metal compound layer, and further including transporting the continuous substrate to a second SALD station and depositing a second metal compound layer over the active absorber layer.
77. The method according to any of embodiments 71-76, further including transporting the continuous substrate to a first carrier transport layer deposition station and forming a first carrier transport layer prior to the transporting to the photoactive layer station.
78. The method according to any of embodiments 71-77, further including transporting the continuous substrate to a second carrier transport layer deposition station and forming a second carrier transport layer over the active absorber layer.
79. The method according to any of embodiments 71-78, further including transporting the continuous substrate to a first patterned metal deposition station and forming a bottom set of metal lines over the continuous substrate, wherein the bottom set of metal lines form at least a portion of a bottom electrode.
80 The method according to any of embodiments 71-79, further including transporting the continuous substrate to a second patterned metal deposition station and forming a top set of metal lines over the continuous substrate, wherein the top set of metal lines form at least a portion of a top electrode.
81. The method according to any of embodiments 57-80, further including transporting the continuous substrate to a reduced-pressure metal oxide deposition station and depositing a metal oxide layer over the continuous substrate, wherein the reduced pressure metal oxide deposition station includes an entry slot and an exit slot through which the continuous substrate enters and exits the reduced pressure metal oxide deposition station, and wherein the entry and exit slots each have a slot height that is less than 3× the splice thickness.
82. The method of embodiment 81, wherein the metal oxide layer deposited at the reduced-pressure metal oxide deposition station includes a conductive metal oxide.
83. The method of embodiment 82, wherein the conductive metal oxide includes ITO or AZO.
84. The method according to any of embodiments 81-83, wherein the metal oxide layer deposited at the reduced-pressure metal oxide deposition station forms part of a top electrode or bottom electrode.
85. The method according to any of embodiments 57-84, wherein the photovoltaic structure includes a transparent top electrode.
86. The method of embodiment 85, wherein the photovoltaic structure includes a transparent bottom electrode.
87. The method of embodiment 85, wherein the photovoltaic structure includes a bottom electrode that is less transparent than the top electrode.
88. The method according to any of embodiments 57-87, wherein the continuous substrate is transported from one station to another at an average speed of at least 5 meters per min.
89. The method according to any of embodiments 57-88, wherein the second substrate includes a pre-splice bottom electrode formed on the second substrate prior to splicing.
90. The method of embodiment 89, wherein the pre-splice bottom electrode includes a composite conductor structure.
91. The method of embodiment 89, wherein the pre-splice bottom electrode includes aluminum.
92. The method according to any of embodiments 57-91, wherein the first and second substrates include PET, PEN or polycarbonate.
93. A method of making a photovoltaic structure by roll-to-roll manufacturing, the method including conveying a continuous substrate from a dispensing roll at ambient pressure to a reduced pressure metal oxide deposition station, depositing a metal oxide layer over the continuous substrate under reduced pressure, and transporting the continuous substrate having the metal oxide layer to a take up roll at ambient pressure, wherein the continuous substrate extends continuously from the dispensing roll to the take up roll.
94. The method of embodiment 93, wherein the reduced pressure metal oxide deposition station includes an entry slot and an exit slot through which the continuous substrate enters and exits the reduced pressure metal oxide deposition station
95. The method of embodiment 94, wherein the reduced pressure metal oxide deposition station further includes:
a) an entry chamber including the entry slot for receiving the continuous substrate, wherein the entry chamber is at an average pressure less than ambient pressure;
b) a metal oxide deposition chamber adjacent to the entry chamber, wherein the metal oxide deposition chamber is at a lower average pressure than the entry chamber; and
c) an exit chamber adjacent to the metal oxide deposition chamber and opposite the entry chamber, wherein the exit chamber includes the exit slot through which the continuous substrate exits, and wherein the exit chamber is at an average pressure that is higher than the metal oxide deposition chamber and lower than ambient pressure.
96. The method according to any of embodiments 93-95, wherein the reduced pressure metal oxide deposition station deposits a transparent conducting layer that forms at least part of a photovoltaic structure electrode.
97. The method of embodiment 96, wherein the photovoltaic structure electrode is a composite conductor including the transparent conducting layer in contact with a set of patterned metal lines.
98. The method according to any of embodiments 93-97, wherein depositing the metal oxide includes aerosol deposition.
99. The method according to any of embodiments 93-98, wherein the metal oxide layer includes ITO or AZO.
100. The method according to any of embodiments 93-99, wherein the continuous substrate includes a splice connecting a first PV substrate and a second PV substrate.
101. The method of embodiment 100, wherein the splice is characterized by a splice thickness that is equal to or less than 3× the sum of a first substrate thickness and a second substrate thickness, or optionally equal to or less than 1.5× the sum of the first substrate thickness and the second substrate thickness.
102. The method of embodiment 100 or 101, wherein the reduced pressure metal oxide deposition station includes an entry slot and an exit slot each characterized by a slot height that is less than 2× the splice thickness.
103. The method of embodiment 102, wherein the slot height is less than 1.5× the splice thickness.
104. The method according to any of embodiments 102-103, wherein one or each slot height is at least 1.05× the splice thickness.
105. The method according to any of embodiments 102-104, wherein one or each slot is an adjustable-height slot, the method further including changing the slot height when the splice traverses the adjustable height slot.
106. The method according to any of embodiments 93-105, further including transporting the continuous substrate to a photoactive layer deposition station including at least an active absorber material coating apparatus and forming an active absorber layer over the continuous substrate by depositing and drying a liquid active absorber material mixture.
107. The method of embodiment 106, wherein the active absorber material includes a perovskite material and the active absorber layer is a perovskite absorber layer.
108. The method of embodiment 106 or 107, wherein forming the active absorber layer includes the use of a gravure cylinder, slot die deposition, anilox cylinder, offset cylinder, or flexography.
109. The method according to any of embodiments 106-108, wherein the continuous substrate is transported to the photoactive layer deposition station prior to transporting to the reduced pressure metal oxide deposition station.
110. The method according to any of embodiments 106-108, wherein the continuous substrate is transported to the photoactive layer deposition station after transporting to the reduced pressure metal oxide deposition station.
111. The method of embodiment 110, wherein the reduced pressure metal oxide deposition station is a first reduced pressure metal oxide deposition station that deposits a first metal oxide layer, and further including transporting the continuous substrate to a second reduced pressure metal oxide deposition station and depositing a second metal oxide layer over the active absorber layer.
112. The method of embodiment 111, wherein depositing the second metal oxide layer includes aerosol deposition.
113. The method of embodiment 111 or 112, wherein the second metal oxide includes ITO or AZO.
114. The method according to any of embodiments 93-113, further including transporting the continuous substrate to a patterned metal deposition station and forming a set of metal lines over the continuous substrate.
115. The method of embodiment 114, wherein the set of metal lines is formed by printing a metal-containing ink.
116. The method of embodiment 115, wherein printing the metal-containing ink includes flexographic printing or gravure printing.
117. The method of embodiment 115 or 116, wherein the metal-containing ink includes silver or copper.
118. The method according to any of embodiments 114-117, wherein the continuous substrate is transported to the patterned metal deposition station prior to transporting to the reduced pressure metal oxide deposition station.
119. The method of embodiment 118, wherein the set of metal lines is part of a composite bottom electrode.
120. The method of embodiment 119, wherein the composite bottom electrode further includes a transparent conducting layer including the metal oxide layer deposited over the set of metal lines.
121. The method according to any of embodiments 114-117, wherein the continuous substrate is transported to the patterned metal deposition station after transporting to the reduced pressure metal oxide deposition station.
122. The method of embodiment 121, wherein the set of metal lines is part of a composite top electrode.
123. The method of embodiment 122, wherein the composite top electrode further includes a transparent conducting layer including the metal oxide layer, over which the set of metal lines is deposited.
124. The method according to any of embodiments 93-123, further including transporting the continuous substrate to a spatial atomic layer deposition tool and depositing a metal compound layer over the continuous substrate.
125. The method of embodiment 124, wherein the metal compound layer includes a metal oxide.
126. The method of embodiment 124 or 125, wherein the metal compound layer is electrically conductive and forms at least part of a photovoltaic structure electrode.
127. The method according of embodiment 124 or 125, wherein the metal compound layer is a passivation layer that impedes the diffusion of metal ions or halide ions or both.
128. The method according to any of embodiments 124-127, wherein the metal compound layer has a thickness of 10 nm or less.
129. The method according to any of embodiments 93-128, wherein the photovoltaic structure includes a transparent top electrode.
130. The method of embodiment 129, wherein the photovoltaic structure includes a transparent bottom electrode.
131. The method of embodiment 129, wherein the photovoltaic structure includes a bottom electrode that is less transparent than the top electrode.
132. The method according to any of embodiments 93-131, wherein the continuous substrate is transported from one station to another at an average speed of at least 5 meters per min.
133. The method according to any of embodiments 93-132, wherein the continuous substrate includes PET, PEN, or polycarbonate.
134. A method of making a photovoltaic structure by roll-to-roll manufacturing, the method including conveying a continuous substrate from a dispensing roll through a series of processing stations to a take up roll, wherein the continuous substrate extends continuously from the dispensing roll to the take up roll, and wherein the series of processing stations includes i) a spatial atomic layer deposition station, and ii) a photoactive layer deposition station including at least an active absorber material coating apparatus.
135. The method of embodiment 134, wherein the continuous substrate is conveyed to the spatial atomic layer deposition station prior to conveying to the photoactive layer deposition station.
136. The method of embodiment 134, wherein the continuous substrate is conveyed to the photoactive layer deposition station prior to conveying to the spatial atomic layer deposition station.
137. The method according to any of embodiments 134-136, further including, at the photoactive layer deposition, forming an active absorber layer over the continuous substrate by depositing and drying a liquid active absorber material mixture.
138. The method of embodiment 137, wherein the active absorber material includes a perovskite material and the active absorber layer is a perovskite absorber layer.
139. The method of embodiment 137 or 138, wherein forming the active absorber layer includes the use of a gravure cylinder, slot die deposition, anilox cylinder, offset cylinder, or flexography.
140. The method according to any of embodiments 134-138, further including depositing a metal compound layer over the continuous substrate at the spatial atomic layer deposition station.
141. The method of embodiment 140, wherein the metal compound layer includes a metal oxide.
142. The method of embodiment 140 or 141, wherein the metal compound layer is electrically conductive and forms at least part of a photovoltaic structure electrode.
143. The method according of embodiment 140 or 141, wherein the metal compound layer is a passivation layer that impedes the diffusion of metal ions or halide ions or both.
144. The method according to any of embodiments 140-143, wherein the metal compound layer has a thickness of 10 nm or less.
145. The method according to any of embodiments 134-144, further including transporting the continuous substrate to a patterned metal deposition station and forming a set of metal lines over the continuous substrate.
146. The method of embodiment 145, wherein the set of metal lines is formed by printing a metal-containing ink.
147. The method of embodiment 146, wherein printing the metal-containing ink includes flexographic printing or gravure printing.
148. The method of embodiment 146 or 147, wherein the metal-containing ink includes silver or copper.
149. The method according to any of embodiments 145-148, wherein the continuous substrate is transported to the patterned metal deposition station prior to transporting to the spatial atomic layer deposition station.
150. The method according to any of embodiments 145-140, wherein the set of metal lines is part of a composite bottom electrode.
151. The method of embodiment 150, wherein the composite bottom electrode further includes a transparent conducting layer including a conductive metal oxide layer deposited over the set of metal lines at the spatial atomic layer deposition station.
152. The method according to any of embodiments 145-148, wherein the continuous substrate is transported to the patterned metal deposition station after transporting to the spatial atomic layer deposition station.
153. The method of embodiment 152 wherein the set of metal lines is part of a composite top electrode.
154. The method of embodiment 153, wherein the composite top electrode further includes a transparent conducting layer including a conductive metal oxide layer deposited at the spatial atomic layer deposition station, over which the set of metal lines is deposited.
155. The method according to any of embodiments 134-154, further including transporting the continuous substrate to a reduced-pressure metal oxide deposition station and depositing a metal oxide layer over the continuous substrate, wherein the reduced pressure metal oxide deposition station includes an entry slot and an exit slot through which the continuous substrate enters and exits the reduced pressure metal oxide deposition station.
156. The method of embodiment 155, wherein the reduced pressure metal oxide deposition station further includes:
a) an entry chamber including the entry slot for receiving the continuous substrate, wherein the entry chamber is at an average pressure less than ambient pressure;
b) a metal oxide deposition chamber adjacent to the entry chamber, wherein the metal oxide deposition chamber is at a lower average pressure than the entry chamber; and
c) an exit chamber adjacent to the metal oxide deposition chamber and opposite the entry chamber, wherein the exit chamber includes the exit slot through which the continuous substrate exits, and wherein the exit chamber is at an average pressure that is higher than the metal oxide deposition chamber and lower than ambient pressure.
157 The method according to any of embodiments 134-156, wherein the photovoltaic structure includes a transparent top electrode.
158. The method of embodiment 157, wherein the photovoltaic structure includes a transparent bottom electrode.
159. The method of embodiment 157, wherein the photovoltaic structure includes a bottom electrode that is less transparent than the top electrode.
160. The method according to any of embodiments 134-159, wherein the continuous substrate is transported from one station to another at an average speed of at least 5 meters per min.
161. The method according to any of embodiments 134-160, wherein the continuous substrate includes PET, PEN, or polycarbonate.
162. A continuous roll-to-roll manufacturing system for making a photovoltaic structure, the manufacturing system including in sequence:
a) a splicing station at ambient pressure for splicing an end portion of a first PV substrate roll to a starting portion of a second PV substrate roll thereby forming a continuous substrate including a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness;
b) an optional first patterned metal deposition station for printing a bottom set of metal lines over the continuous substrate;
c) an optional bottom conducting layer deposition station for depositing a bottom conducting layer over and in contact with the bottom set of metal lines to form a bottom electrode;
d) a first carrier transport layer deposition station for depositing a first carrier transport layer over the bottom electrode;
e) a photoactive layer deposition station including a solution coating apparatus for forming a photoactive absorber layer over the first carrier transport layer;
f) a second carrier transport layer deposition station for depositing a second carrier transport layer over the photoactive absorber layer;
g) a transparent top conducting layer deposition station for depositing a top conducting layer over the second carrier transport layer; and
h) a second patterned metal deposition station for printing a top set of metal lines over and in contact with the top conducting layer to form a transparent top electrode.
163. The manufacturing system of embodiment 162, wherein at least one of the bottom conducting layer deposition station and the top conducting layer deposition is a reduced-pressure metal oxide deposition station for depositing a conductive metal oxide layer, wherein the reduced pressure metal oxide deposition station includes an entry slot and an exit slot through which the continuous substrate enters and exits the reduced pressure metal oxide deposition station, and wherein the entry and exit slots each have a slot height that is less than 3× the splice thickness.
164. The manufacturing system of embodiment 163, wherein one or each slot height is less than 2× the splice thickness.
165. The manufacturing system of embodiment 163, wherein one or each slot height is less than 1.5× the splice thickness.
166. The manufacturing system according to any of embodiments 163-165, wherein one or each slot height is at least 1.05× the splice thickness.
167. The manufacturing system according to any of embodiments 163-166, wherein one or each slot is an adjustable-height slot.
168. The manufacturing system according to any of embodiments 163-167, wherein the reduced pressure metal oxide deposition station further includes:
i) an entry chamber including the entry slot for receiving the continuous substrate, wherein the entry chamber is at an average pressure less than ambient pressure;
ii) a metal oxide deposition chamber adjacent to the entry chamber, wherein the metal oxide deposition chamber is at a lower average pressure than the entry chamber; and
iii) an exit chamber adjacent to the metal oxide deposition chamber and opposite the entry chamber, wherein the exit chamber includes the exit slot through which the continuous substrate exits, and wherein the exit chamber is at an average pressure that is higher than the metal oxide deposition chamber and lower than ambient pressure.
169. The manufacturing system according to any of embodiments 163-168, wherein the reduced pressure metal oxide deposition station includes an aerosol deposition tool.
170. The manufacturing system according to any of embodiments 162-169, wherein at least one of the bottom conducting layer deposition station and the top conducting layer deposition is a spatial atomic layer deposition station for depositing a conductive metal oxide layer.
171. The manufacturing system according to any of embodiments 162-170, further including a passivation layer deposition station for depositing a passivation layer.
172. The manufacturing system of embodiment 171, wherein the passivation layer deposition station includes a passivation spatial atomic layer deposition tool.
173. The manufacturing system of embodiment 171 or 172, wherein the passivation layer includes a passivating metal compound.
174. The manufacturing system of embodiment 173, wherein the passivating metal compound includes a passivating metal oxide.
175. The manufacturing system according to any of embodiments 171-174, wherein the passivation layer has a thickness of 6 nm or less.
176. The manufacturing system according to any of embodiments 171-175, wherein the passivation layer deposition tool is positioned:
i) between (c) and (d);
ii) between (d) and (e);
iii) between (e) and (f);
iv) between (f) and (g); or
v) after (h).
177. The manufacturing system according to any of embodiments 162-176, wherein the bottom conducting layer deposition station includes bottom conducting layer coating apparatus for depositing carbon nanotubes or metal nanowires.
178. The manufacturing system according to any of embodiments 162-177, wherein at least one of the first patterned metal deposition station and the second patterned metal deposition station includes a flexographic printer or a gravure printer.
179. The manufacturing system according to any of embodiments 162-178, wherein the bottom set of metal lines includes silver or copper.
180. The manufacturing system according to any of embodiments 162-179, wherein the top set of metal lines includes silver.
181. The manufacturing system according to any of embodiments 162-179, wherein the top set of metal lines includes copper.
182. The manufacturing system according to any of embodiments 162-181, wherein the second PV substrate includes a pre-splice bottom electrode and the manufacturing system does not include (b) or (c).
183. The manufacturing system of embodiment 182, wherein the pre-splice bottom electrode includes a composite conductor structure.
184. The manufacturing system of embodiment 182, wherein the pre-splice bottom electrode includes aluminum.
185. The manufacturing system according to any of embodiments 162-184, wherein the first and second substrates include PET, PEN, or polycarbonate.
186. The manufacturing system according to any of embodiments 162-185, wherein the photovoltaic structure includes a transparent top electrode.
187. The manufacturing system of embodiment 186, wherein the photovoltaic structure includes a transparent bottom electrode.
188. The manufacturing system of embodiment 186, wherein the photovoltaic structure includes a bottom electrode that is less transparent than the top electrode.
189. The manufacturing system according to any of embodiments 162-188, further including a drive system capable of transporting the continuous substrate at an average speed of at least 5 meters per minute during roll-to-roll manufacturing.
190. A method according to any one of embodiments 1-56, 81-84, and 102-105, wherein (i) the splice is an overlap splice or a butt splice, and the splice thickness is less than or equal to equal to 1.5 times the sum of the thicknesses of the first substrate and the second substrate for an overlap splice, and the splice thickness is less than or equal to 1.5 times either of the first substrate thickness or the second substrate thickness for a butt slice; (ii) the ratio of at least one or each slot height to splice thickness is maintained in a range of 1.05-2.0, and the ratio of at least one or each slot height to each of the first and second substrate thickness away from the splice is maintained in a range of 1.05-4.0.

Although the present disclosure has been made with perovskite photovoltaic structures in mind, various embodiments of the manufacturing system described are generally compatible with some other PV systems such as organic PV structures. For example, a perovskite absorber layer deposition station may instead be referred to generally as a photoactive layer deposition station that forms an active absorber layer. The active absorber layer may include a material other than perovskite.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of example embodiments of the invention has been presented for the purposes of illustration and description. It is not intended to be exhaustive or to limit the invention to the precise form described, and many modifications and variations are possible in light of the teaching above.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Additionally, details of any specific embodiment may not always be present in variations of that embodiment or may be added to other embodiments. It should be noted that, unless otherwise explicitly noted or required by context, the word “or” is used in this disclosure in a non-exclusive sense.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the device” includes reference to one or more devices and equivalents thereof known to those skilled in the art, and so forth. The invention has now been described in detail for the purposes of clarity and understanding. However, it will be appreciated that certain changes and modifications may be practice within the scope of the appended claims.

All publications, patents, and patent applications cited herein are hereby incorporated by reference in their entirety for all purposes. None is admitted to be prior art.

We claim:

1. A method of making a photovoltaic structure by roll-to-roll manufacturing, the method comprising conveying a continuous substrate from a dispensing roll at ambient pressure to a reduced pressure metal oxide deposition station, depositing a metal oxide layer over the continuous substrate under reduced pressure, and transporting the continuous substrate having the metal oxide layer to a take up roll at ambient pressure, wherein the continuous substrate extends continuously from the dispensing roll to the take up roll.

2. The method of claim 1, wherein the reduced pressure metal oxide deposition station comprises an entry slot and an exit slot through which the continuous substrate enters and exits the reduced pressure metal oxide deposition station.

3. The method of claim 2, wherein the reduced pressure metal oxide deposition station further comprises:
a) an entry chamber comprising the entry slot for receiving the continuous substrate, wherein the entry chamber is at an average pressure less than ambient pressure;
b) a metal oxide deposition chamber adjacent to the entry chamber, wherein the metal oxide deposition chamber is at a lower average pressure than the entry chamber; and
c) an exit chamber adjacent to the metal oxide deposition chamber and opposite the entry chamber, wherein the exit chamber comprises the exit slot through which the continuous substrate exits, and wherein the exit chamber is at an average pressure that is higher than the metal oxide deposition chamber and lower than ambient pressure.

4. The method according to any one of claims 1-3, wherein the reduced pressure metal oxide deposition station deposits a transparent conducting layer that forms at least part of a photovoltaic structure electrode.

5. The method of claim 4, wherein the photovoltaic structure electrode is a composite conductor comprising the transparent conducting layer in contact with a set of patterned metal lines.

6. The method of claim 1, wherein depositing the metal oxide comprises aerosol deposition.

7. The method of claim 1, wherein the metal oxide layer comprises ITO or AZO.

8. The method of claim 1, wherein the continuous substrate comprises a splice connecting a first PV substrate and a second PV substrate.

9. The method of claim 8, wherein the splice is formed by:
splicing an end portion of a first PV substrate roll to a starting portion of a second PV substrate roll at a splicing station at ambient pressure, thereby forming the continuous substrate comprising a splice, wherein the end portion is characterized by a first substrate thickness, the starting portion is characterized by a second substrate thickness, and the splice is characterized by a splice thickness that is equal to or less than 3× the sum of first substrate thickness and the second substrate thickness, or optionally equal to or less than 1.5× the sum of the first substrate thickness and the second substrate thickness.

10. The method of claim 8, wherein the splice is characterized by a splice thickness that is equal to or less than 3× the sum of a first substrate thickness and a second substrate thickness, or optionally equal to or less than 1.5× the sum of the first substrate thickness and the second substrate thickness.

11. The method of claim 8, 9 or 10, wherein the reduced pressure metal oxide deposition station comprises an entry slot and an exit slot each characterized by a slot height that is less than 2× the splice thickness.

12. The method of claim 11, wherein the slot height is less than 1.5× the splice thickness.

13. The method of claim 11, wherein one or each slot height is at least 1.05× the splice thickness.

14. The method of claim 11, wherein one or each slot is an adjustable-height slot, the method further comprising changing the slot height when the splice traverses the adjustable height slot.

15. The method of claim 11, wherein (i) the splice is an overlap splice or a butt splice, and the splice thickness is less than or equal to equal to 1.5 times the sum of the thicknesses of the first substrate and the second substrate for an overlap splice, and the splice thickness is less than or equal to 1.5 times either of the first substrate thickness or the second substrate thickness for a butt slice; (ii) the ratio of at least one or each slot height to splice thickness is maintained in a range of 1.05-2.0, and the ratio of at least one or each slot height to each of the first and second substrate thickness away from the splice is maintained in a range of 1.05-4.0.

16. The method of claim 1, further comprising transporting the continuous substrate to a photoactive layer deposition station comprising at least an active absorber material coating apparatus and forming an active absorber layer over the continuous substrate by depositing and drying a liquid active absorber material mixture.

17. The method of claim 16, wherein the active absorber material comprises a perovskite material and the active absorber layer is a perovskite absorber layer.

18. The method of claim 16 or 17, wherein forming the active absorber layer comprises the use of a gravure cylinder, slot die deposition, anilox cylinder, offset cylinder, or flexography.

19. The method of claim 16 or 17, wherein the continuous substrate is transported to the photoactive layer deposition station prior to transporting to the reduced pressure metal oxide deposition station.

20. The method of claim 16 or 17, wherein the continuous substrate is transported to the photoactive layer deposition station after transporting to the reduced pressure metal oxide deposition station.

21. The method of claim 20, wherein the reduced pressure metal oxide deposition station is a first reduced pressure metal oxide deposition station that deposits a first metal oxide layer, and further comprising transporting the continuous substrate to a second reduced pressure metal oxide deposition station and depositing a second metal oxide layer over the active absorber layer.

22. The method of claim 21, wherein depositing the second metal oxide layer comprises aerosol deposition.

23. The method of claim 21, wherein the second metal oxide comprises ITO or AZO.

24. The method of claim 1, further comprising transporting the continuous substrate to a patterned metal deposition station and forming a set of metal lines over the continuous substrate.

25. The method of claim 24, wherein the set of metal lines is formed by printing a metal-containing ink.

26. The method of claim 25, wherein printing the metal-containing ink comprises flexographic printing or gravure printing.

27. The method of claim 25 or 26, wherein the metal-containing ink comprises silver or copper.

28. The method of claim 24 or 25, wherein the continuous substrate is transported to the patterned metal deposition station prior to transporting to the reduced pressure metal oxide deposition station.

29. The method of claim 28, wherein the set of metal lines is part of a composite bottom electrode.

30. The method of claim 29, wherein the composite bottom electrode further comprises a transparent conducting layer comprising the metal oxide layer deposited over the set of metal lines.

31. The method of claim 24 or 25, wherein the continuous substrate is transported to the patterned metal deposition station after transporting to the reduced pressure metal oxide deposition station.

32. The method of claim 31, wherein the set of metal lines is part of a composite top electrode.

33. The method of claim 32, wherein the composite top electrode further comprises a transparent conducting layer comprising the metal oxide layer, over which the set of metal lines is deposited.

34. The method of claim 1, further comprising transporting the continuous substrate to a spatial atomic layer deposition tool and depositing a metal compound layer over the continuous substrate.

35. The method of claim 34, wherein the metal compound layer comprises a metal oxide.

36. The method of claim 34 or 35, wherein the metal compound layer is electrically conductive and forms at least part of a photovoltaic structure electrode.

37. The method of claim 34 or 35, wherein the metal compound layer is a passivation layer that impedes the diffusion of metal ions or halide ions or both.

38. The method of claim 34 or 35, wherein the metal compound layer has a thickness of 10 nm or less.

39. The method of claim 1, wherein the photovoltaic structure comprises a transparent top electrode.

40. The method of claim 39, wherein the photovoltaic structure comprises a transparent bottom electrode.

41. The method of claim 39, wherein the photovoltaic structure comprises a bottom electrode that is less transparent than the top electrode.

42. The method of claim 1, wherein the continuous substrate is transported from one station to another at an average speed of at least 5 meters per min.

43. The method of claim 1, wherein the continuous substrate comprises PET, PEN, or polycarbonate.
